(19) United States
(12) Patent Application Publication
(10) Pub. No.: US 2016/0141233 A1
(43) Pub. Date: May 19, 2016

(54) FIRST-PACKAGED AND LATER-ETCHED NORMAL CHIP THREE DIMENSION SYSTEM-IN-PACKAGE METAL CIRCUIT BOARD STRUCTURE AND PROCESSING METHOD THEREOF

(71) Applicant: JIANGSU CHANGJIANG ELECTRONICS TECHNOLOGY CO., LTD, Jiangsu (CN)

(72) Inventors: Steve Xin Liang, Jiangsu (CN); Chih-Chung Liang, Jiangsu (CN); Yu-Bin Lin, Jiangsu (CN); Yaqin Wang, Jiangsu (CN); Youhai Zhang, Jiangsu (CN)

(21) Appl. No.: 14/901,411

(22) PCT Filed: Jan. 7, 2014
(86) PCT No.: PCT/CN2014/000018

§ 371 Date: Dec. 28, 2015

(30) Foreign Application Priority Data
Aug. 6, 2013 (CN) 201310340527.4

(51) Int. Cl. H01L 23/495; H01L 21/56; H01L 25/00; H01L 23/498; H01L 23/00; H01L 21/48; H01L 23/29

(52) U.S. Cl. CPC H01L 23/49575; H01L 21/4853; H01L 21/4825; H01L 21/4857; H01L 21/561; H01L 21/568; H01L 23/293; H01L 23/49811; H01L 23/49822; H01L 24/16; H01L 24/32; H01L 24/45; H01L 25/50; H01L 2224/16258; H01L 2224/2919; H01L 2224/32013; H01L 2224/45147; H01L 2224/48091; H01L 2224/48137; H01L 2224/73204; H01L 2224/73265; H01L 2924/0781; H01L 2924/18165

(57) ABSTRACT

The present invention relates to a first-packaged and later-etched normal chip three dimension-on-chip metal circuit board structure and a processing method for manufacturing the same, the structure includes: metal substrate frame (1); a lead (3) provided in the metal substrate frame (1); a conductive pillar (4) provided in a top surface of the lead (3); a chip is mounted normally on a top surface of the metal circuit frame (1) or between the leads (3); a metal wire (6) via which a top surface of the chip (5) is connected to a top surface of the lead (3); a molding material (8) with which a periphery region of the lead (3), the conductive pillar (4), the chip (5) and the metal wire (6) is encapsulated, with the molding material (8) being flushed with a top of the conductive pillar (4).

### CROSS-REFERENCE TO RELATED APPLICATIONS

This application claims the priority of Chinese Patent Application No. 201310340527.4, entitled “FIRST-PACKAGED AND LATER-ETCHED NORMAL CHIP THREE-DIMENSIONAL SYSTEM-IN-PACKAGE METAL CIRCUIT BOARD STRUCTURE AND PROCESSING METHOD THEREOF”, filed with the Chinese Patent Office on Aug. 6, 2013, which is incorporated by reference in its entirety herein.

### FIELD

The present invention relates to a first-packaged and later-etched normal chip three dimension system-in-package metal circuit board structure and processing method thereof, which belongs to a technical field of semiconductor packaging.

### BACKGROUND

Basic processing methods for manufacturing a conventional metal lead frame are as follows.

1. A metal sheet is provided to be punched from up to down or from down to up in a longitudinal manner by a punching technology using a mechanical upper and lower tool (see FIG. 91), such that a lead frame with a die pad for supporting a chip, an inner lead for transmitting a signal and an outer lead for connecting to an external PCB (printed circuit board) can be formed in the metal sheet, thereafter certain regions of the inner lead and/or the die pad are coated with a metal plating layer to form a lead frame which can be actually used (see FIG. 92, FIG. 93).

2. A metal sheet is provided to be exposed and developed to form a window and to be chemically etched by the technology of chemical etching (see FIG. 94), such that a lead frame with a die pad for supporting a chip, an inner lead for transmitting a signal and an external lead for connecting to an external PCB can be formed in the metal sheet, thereafter certain regions of the inner lead and/or the die pad are coated with a metal plating layer to form a lead frame that can be actually used (see FIG. 95).

3. Another method is as follows. Applying a layer of high temperature resistant adhesive film which can resist 220 □ is on a bottom surface of the lead frame, after a lead frame with a die pad for supporting a chip, an inner lead for transmitting signal and an external lead for connecting to an external PCB has been formed and certain regions of the inner lead and/or the die pad have been coated with a metal plating layer based on a first method and a second method, such that the lead frame becomes a lead frame which can be used in a QFN (Quad Flat No Lead) package and a molding volume shrunk package (see FIG. 96).

4. Yet another method is as follows. Pre-molding is performed on a lead frame, after the lead frame with a die pad for supporting a chip, an inner lead for transmitting signal and an outer lead for connecting to an external PCB has been formed and certain regions of the inner lead and/or the die pad have been coated with a metal plating layer utilizing the first method or the second method, a thermosetting epoxy resin is filled in a region where the metal sheet has been punched or been chemically etched, such that the lead frame becomes a pre-molded lead frame which can be used in a QFN package, a molding volume shrunk package and a copper wire bonding package (see FIG. 97).

### SUMMARY

A processing method for manufacturing a first-packaged and later-etched normal chip three dimension system-in-package metal circuit board structure is provided, which includes:
step 1: providing a metal substrate;
step 2: pre-plating a surface of the metal substrate with a copper material,
wherein the surface of the metal substrate is pre-plated with a layer of copper material;
step 3: applying a photoresist film,
wherein a top surface and a bottom surface of the metal substrate which have been pre-plated with the copper material in step 2 are respectively pasted with the photoresist film which can be exposed and developed;
step 4: removing a part of the photoresist film on the top surface of the metal substrate,
wherein the top surface of the metal substrate which has been pasted with the photoresist film in step 3 is exposed and developed with a pattern using an exposure and development equipment, and the part of the photoresist film in the pattern is removed, so as to expose a region of the top surface of the metal substrate to be plated with a metal wiring layer later;
step 5: plating with the metal wiring layer,
wherein the region of the top surface of the metal substrate from which the part of the photoresist film has been removed in step 4 is plated with the metal wiring layer, so that a die pad and a lead are formed on the top surface of the metal substrate;

step 6: applying a photoresist film,
wherein the top surface of the metal substrate which has been plated with the metal wiring layer in step 5 is pasted with the photoresist film which can be exposed and developed;
step 7: removing a part of the photoresist film on the top surface of the metal substrate,
wherein the top surface of the metal substrate which has been pasted with the photoresist film in step 6 is exposed and developed with a pattern using an exposure and development equipment, and the part of the photoresist film in a pattern is removed, so as to expose a region of the top surface of the metal substrate to be plated with a conductive pillar later;
step 8: plating with the conductive pillar,
wherein the region of the top surface of the metal substrate from which a part of the photoresist film has been removed in step 7 is plated with the conductive pillar;
step 9: removing the photoresist film,
wherein the photoresist film on the surface of the metal substrate is removed;
step 10: bonding die,
wherein a chip is embedded in a top surface of the die pad formed in step 5 by coating with a conductive or non-conductive adhesive material;
step 11: bonding a metal wire,
wherein the metal wire is bonded between a top surface of the chip and the lead formed in step 5;
step 12: molding with an epoxy resin,
wherein the molding with the epoxy resin for protecting is performed on the top surface of the metal substrate after the bonding die and the metal wire bonding have been performed;
step 13: grinding a surface of the epoxy resin,
wherein the surface of the epoxy resin is ground after molding with the epoxy resin has been performed in step 12;
step 14: applying a photoresist film,
wherein the top surface and the bottom surface of the metal substrate are pasted with the photoresist film which can be exposed and developed after the surface of the epoxy resin has been ground in step 13;
step 15: removing a part of the photoresist film on the bottom surface of the metal substrate,
wherein the bottom surface of the metal substrate, which has been pasted with the photoresist film in step 14, is exposed and developed with a pattern using an exposure and development equipment, and the part of the photoresist film in the pattern is removed, so as to expose a region of the bottom surface of the metal substrate to be etched later;
step 16: etching,
wherein chemical etching is performed in the region of the bottom surface of the metal substrate from which the part of the photoresist film has been removed in step 15;
step 17: removing the photoresist film,
wherein the photoresist film on the surface of the metal substrate is removed, the photoresist film is removed by softening with chemicals and cleaning with high pressure water; and
step 18: plating with an anti-oxidizing metal layer or coating with an organic solderability preservative (OSP),
wherein an exposed metal surface of the metal substrate surface from which the photoresist film has been removed in step 17 is plated with the anti-oxidizing metal layer or is coated with the organic solderability preservative (OSP).

A processing method for manufacturing a first-packaged and later-etched normal chip three dimension system-in-package metal circuit board structure is provided, which includes:
step 1: providing a metal substrate;
step 2: pre-plating a surface of the metal substrate with a copper material,
wherein the surface of the metal substrate is pre-plated with a layer of copper material;
step 3: applying a photoresist film,
wherein a top surface and a bottom surface of the metal substrate which have been pre-plated with the copper material in step 2 are respectively pasted with the photoresist film which can be exposed and developed;
step 4: removing a part of the photoresist film on the top surface of the metal substrate,
wherein the top surface of the metal substrate, which has been pasted with the photoresist film in step 3 is exposed and developed with a pattern using an exposure and development equipment, and the part of the photoresist film in the pattern is removed, so as to expose a region of the top surface of the metal substrate to be plated with a metal wiring layer later;
step 5: plating with the metal wiring layer,
wherein the region of the top surface of the metal substrate from which the part of the photoresist film has been removed in step 4 is plated with the metal wiring layer, so that a die pad and a lead are formed on the top surface of the metal substrate;
step 6: applying a photoresist film,
wherein the top surface of the metal substrate which has been plated with the metal wiring layer in step 5 is pasted with the photoresist film which can be exposed and developed;
step 7: removing a part of the photoresist film on the top surface of the metal substrate,
wherein the top surface of the metal substrate which has been pasted with the photoresist film in step 6 is exposed and developed with a pattern using an exposure and development equipment, and the part of the photoresist film in a pattern is removed, so as to expose a region of the top surface of the metal substrate to be plated with a conductive pillar later;
step 8: plating with the conductive pillar,
wherein the region of the top surface of the metal substrate from which a part of the photoresist film has been removed in step 7 is plated with the conductive pillar;
step 9: removing the photoresist film,
wherein the photoresist film on the surface of the metal substrate is removed;
step 10: bonding die,
wherein a chip is in a top surface of the die pad formed in step 5 by coating with a conductive or non-conductive adhesive material;
step 11: bonding a metal wire,
wherein the metal wire is bonded between a top surface of the chip and the lead formed in step 5;
step 12: molding with an epoxy resin,
wherein the molding with the epoxy resin for protecting is performed on the top surface of the metal substrate after the bonding die and the metal wire bonding have been performed;
step 13: grinding a surface of the epoxy resin,
wherein the surface of the epoxy resin is ground after the molding with the epoxy resin has been performed in step 12;
step 14: applying a photoresist film,
wherein the top surface and the bottom surface of the metal substrate are pasted with the photoresist film which can be exposed and developed after the surface of the epoxy resin has been ground in step 13;
step 15: removing a part of the photoresist film on the bottom surface of the metal substrate,
wherein the bottom surface of the metal substrate, which has been pasted with the photoresist film in step 14, is exposed and developed with a pattern using an exposure and development equipment, and the part of the photoresist film in the pattern is removed, so as to expose a region of the bottom surface of the metal substrate to be etched later;
step 16: etching,
wherein chemical etching is performed in the region of the bottom surface of the metal substrate from which the part of the photoresist film has been removed in step 15;
step 17: removing the photoresist film,
wherein the photoresist film on the surface of the metal substrate is removed;
step 18: coating the bottom surface of the metal substrate with a solder mask or photosensitive non-conductive adhesive material,
wherein the bottom surface of the metal substrate is coated with the solder mask or the photosensitive non-conductive adhesive material after the photoresist film has been removed in step 17;
step 19: exposing and developing to form a window,
wherein the solder mask or photosensitive non-conductive adhesive material with which the bottom surface of the metal substrate is coated is exposed an developed using an exposure and development equipment to form the window, so as to expose a region of the bottom surface of the metal substrate to be plated with a high conductivity metal layer later;
step 20: plating with the high conductivity metal layer,
wherein a region of the window formed in the solder mask or photosensitive non-conductive adhesive material on the bottom surface of the metal substrate in step 19 is plated with the high conductivity metal layer; and
step 21: plating with an anti-oxidizing metal layer or coating with an organic solderability preservative (OSP),
wherein an exposed metal surface of the metal substrate is plated with the anti-oxidizing metal layer or be coated with the organic solderability preservative (OSP).

A processing method for manufacturing a first-packaged and later-etched normal chip three dimension system-in-package metal circuit board structure is provided, which includes:
step 1: providing a metal substrate;
step 2: pre-plating the surface of the metal substrate with a copper material,
wherein the surface of the metal substrate is pre-plated with a layer of copper material;
step 3: applying a photoresist film,
wherein a top surface and a bottom surface of the metal substrate which have been pre-plated with the copper material in step 2 are pasted with the photoresist film which can be exposed and developed;
step 4: removing a part of the photoresist film on the top surface of the metal substrate,
wherein the top surface of the metal substrate which has been pasted with the photoresist film in step 3 is exposed and developed with a pattern using an exposure and development equipment, and the part of the photoresist film in the pattern is removed, so as to expose a region of the top surface of the metal substrate to be plated with a first metal wiring layer later;
step 5: plating with a first metal wiring layer,
wherein the region of the top surface of the metal substrate from which a part of the photoresist film has been removed in step 4 is plated with the first metal wiring layer;
step 6: applying a photoresist film,
wherein the top surface of the metal substrate which has been plated with the first metal wiring layer in step 5 is pasted with the photoresist film which can be exposed and developed;
step 7: removing a part of the photoresist film on the top surface of the metal substrate,
wherein the top surface of the metal substrate which has been pasted with the photoresist film in step 6 is exposed and developed with a pattern using an exposure and development equipment, and the part of the photoresist film in the pattern is removed, so as to expose a region of the top surface of the metal substrate to be plated with a second metal wiring layer later;
step 8: plating with the second metal wiring layer,
wherein the region of the top surface of the metal substrate from which the part of the photoresist film has been removed in step 7 is plated with the second metal wiring layer, which servers as a conductive pillar to connect the first metal wiring layer to a third metal wiring layer;
step 9: removing the photoresist film,
wherein the photoresist film on the surface of the metal substrate is removed;
step 10: applying a non-conductive adhesive film,
wherein the top surface of the metal substrate is pasted with a layer of non-conductive adhesive film;
step 11: grinding a surface of the non-conductive adhesive film,
wherein the surface of the non-conductive adhesive film is ground after the applying the non-conductive film has been performed in step 10;
step 12: performing metallization pretreatment on the surface of the non-conductive adhesive film,
wherein the metallization pre-treatment is performed on the surface of the non-conductive adhesive film, so that a layer of metalized polymer material is adhered onto the surface of the non-conductive adhesive film, or roughening treatment is performed on the surface of the non-conductive adhesive film;
step 13: applying a photoresist film,
wherein the top surface and the bottom surface of the metal substrate which have been metallized in step 12 are pasted with the photoresist film which can be exposed and developed;
step 14: removing a part of the photoresist film on the top surface of the metal substrate,
wherein the top surface of the metal substrate, which has been pasted with the photoresist film in step 13 is exposed and developed with a pattern using an exposure and development equipment, and the part of the photoresist film in the pattern is removed, so as to expose a region of the top surface of the metal substrate to be etched later;
step 15: etching,
wherein etching is performed in a region of the top surface of the metal substrate from which the part of the photoresis film has been removed in step 14;
step 16: removing the photoresist film,
wherein the photoresist film on the top surface of the metal substrate is removed;
step 17: plating with a third metal wiring layer,
wherein a remaining metallization pre-treatment region of the top surface of the metal substrate on which the etching has been performed in step 15 is plated with the third wiring layer, so that a die pad and a lead are formed on the top surface of the metal substrate;
step 18: applying a photoresist film,
wherein the top surface of the metal substrate which has been plated with the third metal wiring layer in step 17 is pasted with the photoresist film which can be exposed and developed;
step 19: removing a part of the photoresist film on the top surface of the metal substrate,
wherein the top surface of the metal substrate, which has been applying the photoresist film in step 18, is exposed and developed with a pattern using an exposure and development equipment, and the part of the photoresist film in the pattern is removed, so as to expose a region of the top surface of the metal substrate to be plated with a conductive pillar later;
step 20: plating with the conductive pillar,
wherein the region of the top surface of the metal substrate from which the part of the photoresist film has been removed in step 19 is plated with the conductive pillar;
step 21: removing the photoresist film,
wherein the photoresist film on the surface of the metal substrate is removed;
step 22: bonding die,
wherein a chip is embedded in a top surface of the die pad formed in step 17 by coating with a conductive or non-conductive adhesive material;
step 23: bonding a metal wire,
wherein the metal wire is bonded between a top surface of the chip and the lead formed in step 5;
step 24: molding with epoxy resin,
wherein the molding with the epoxy resin for protecting is performed on the top surface of the metal substrate after the bonding die and the metal wire bonding have been performed;
step 25: grinding a surface of the epoxy resin,
wherein the surface of the epoxy resin is ground after the molding with the epoxy resin has been performed in step 24;
step 26: applying a photoresist film,
wherein the top surface and the bottom surface of the metal substrate are pasted with the photoresist film which can be exposed and developed after the surface of the epoxy resin has been ground in step 25;
step 27: removing a part of the photoresist film on the bottom surface of the metal substrate,
wherein the bottom surface of the metal substrate which has been pasted with the photoresist film in step 26 is exposed and developed with a pattern using an exposure and development equipment, and the part of the photoresist film in the pattern is removed, so as to expose a region of the bottom surface of the metal substrate to be etched later;
step 28: etching,
wherein chemical etching is performed in the region of the bottom surface of the metal substrate from which the part of the photoresist film has been removed in step 27;
step 29: removing the photoresist film,
wherein the photoresist film on the surface of the metal substrate is removed; and
step 30: plating with an anti-oxidizing metal layer or coating with an organic solderability preservative (OSP),
wherein an exposed metal surface of the metal substrate surface from which the photoresist film has been removed in step 29 is plated with the anti-oxidizing metal layer or is coated with the organic solderability preservative (OSP).
Step 6 to step 17 may be repeated for times between step 8 and step 18.

A first-packaged and later-etched normal chip three dimension system-in-package metal circuit board structure is provided, which includes: a metal substrate frame; a die pad and a lead provided in the metal substrate frame; a conductive pillar provided on a top surface of the lead; a normal chip is mounted on a top surface of the die pad by a conductive or non-conductive adhesive material; a metal wire via which a top surface of the chip is connected to a top surface of the lead; a molding material or epoxy resin with which a periphery region of the die pad, the lead, the conductive pillar, the chip and the metal wire are encapsulated, with the molding material or epoxy resin being flushed with a top of the conductive pillar; and an anti-oxidizing layer provided on a surface of the metal substrate frame, the die pad, the lead and a surface of the conductive pillar exposed from the molding material.

A plurality of turns of conductive pillars may be provided.

A passive device may be connected across the top surface of the leads.

An electrostatic discharge coil may be provided between the die pad and the lead, the top surface of the chip may be connected to a top surface of the electrostatic discharge coil via a metal wire.

A plurality of die pads may be provided, the chip may be provided on each of the plurality of die pads, and the top surfaces of the chips may be connected via the metal wire.

A second chip may be mounted normally on the top surface of the chip, and the second chip may be is connected to the lead via the metal wire.

A first-packaged and later-etched normal chip three dimension system-in-package metal circuit board structure is provided, which includes: a metal substrate frame; a lead provided in the metal substrate frame, a conductive pillar provided on a top surface of the lead; a chip is mounted normally on the top surface of the metal substrate frame or between the leads by a conductive or non-conductive adhesive material; a metal wire via which a top surface of the chip is connected to a top surface of the lead; a molding material or epoxy resin with which a periphery region of the lead, the conductive pillar, the chip and the metal wire is encapsulated, with the molding material or epoxy resin being flushed with a top of the conductive pillar; and an anti-oxidizing layer or an organic solderability preservative coating provided on a surface of the metal substrate frame, the lead and the conductive pillar exposed from the molding material.

A first-packaged and later-etched normal chip three dimension system-in-package metal circuit board structure is provided, which includes: a metal substrate frame; a die pad and a lead provided in the metal substrate frame; a conductive pillar provided on a top surface of the lead; a chip is mounted normally on a top surface of the die pad by a conductive or non-conductive adhesive material; a metal wire via which a top surface of the chip is connected to a top surface of the lead; molding material or epoxy resin with which a periphery region of the die pad, the lead, the conductive pillar, the chip and the metal wire are encapsulated, with the molding material or epoxy resin being flushed with a top of the conductive pillar; a high conductivity metal layer provided on a bottom surface of the die pad and the lead; a solder mask or photosensitive non-conductive adhesive material filled between the high conductivity metal layers; and an anti-oxidizing layer or an organic solderability preservative coating provided on a surface of the metal substrate frame, the conductive pillar and the high conductivity metal layer exposed from the molding material or epoxy resin and the solder mask or photosensitive non-conductive adhesive material.

As compared with the prior art, the present invention has beneficial effects as follows.
1. At present, each metal lead frame is manufactured by mechanical punching or chemical etching, multiple metal wiring layers can not be manufactured. And no object can be embedded into an interlayer inside the punching type metal lead frame. However, a three dimension metal wiring composite-type substrate provided in the present invention allows an object to be embedded into an interlayer inside the substrate.
2. A heat conductor or heat sink may be embedded into a required position or region in the interlayer inside the three dimension metal wiring composite-type substrate as required, so as to become a heat performance system-in-package metal lead frame (see FIG. 102).
3. An active element or assembly or a passive assembly may be embedded into a required position or region in the interlayer inside the three dimension metal wiring composite-type substrate as required by the system and function, so as to become a system-in-package metal lead frame.
4. It is totally unable to be found from the appearance of an finished product of the three dimension metal wiring composite-type substrate that an object has been embedded into an inner interlayer as required by system or function, especially an embedded silicon chip can not even be detected by X-ray, and thereby secrecy and protectiveness of the system and function can be sufficiently achieved.
5. A finished product of the three dimension metal wiring composite-type substrate includes various components in itself, if there is no need for a secondary packaging, the three dimension metal wiring composite-type substrate may be cut according to each cell, and each cell becomes an ultra thin package.
6. Except for having a function of implanting an object, the three dimension metal wiring composite-type substrate may be secondary packaged. And thereby an integration of system functions can be sufficiently achieved;
7. Except for having a function of implanting an object, the three dimension metal wiring composite-type substrate may be stacked with different unit package or system-in-package package at the outside of the package, and thereby dual system or multiple systems-on-chip packaging technology ability is sufficiently achieved.
8. The three dimension metal wiring substrate can serve as converter to achieve a connection between chips in different pattern and a connection between the passive elements or a connection between the passive elements and a lead frame in various package-type or a substrate, so as to achieve multiple chip module (MCM) package (see FIG. 103 and FIG. 104). And the three dimension metal wiring composite-type substrate has lower cost and better flexibility than a conventional MCM substrate.

### BRIEF DESCRIPTION OF THE DRAWINGS

FIG. 1 to FIG. 18 are respectively schematic procedure diagrams of a processing method for manufacturing a first-packaged and later-etched normal chip three dimension system-in-package metal circuit board structure according to a first embodiment of the present invention;

FIG. 19 is a schematic diagram of a first-packaged and later-etched normal chip three dimension system-in-package metal circuit board structure according to the first embodiment of the present invention;

FIG. 20 to FIG. 40 are respectively schematic procedure diagrams of a processing method for manufacturing a first-packaged and later-etched normal chip three dimension system-in-package metal circuit board structure according to a second embodiment of the present invention;

FIG. 41 is a schematic diagram of a first-packaged and later-etched normal chip three dimension system-in-package metal circuit board structure according to the second embodiment of the present invention;

FIG. 42 to FIG. 83 are respectively schematic procedure diagrams of a processing method for manufacturing a first-packaged and later-etched normal chip three dimension system-in-package metal circuit board structure according to a third embodiment of the present invention;

FIG. 84 is a schematic diagram of a first-packaged and later-etched normal chip three dimension system-in-package metal circuit board structure according to the third embodiment of the present invention;

FIG. 85 is a schematic diagram of a first-packaged and later-etched normal chip three dimension system-in-package metal circuit board structure according to a fourth embodiment of the present invention;

FIG. 86 is a schematic diagram of a first-packaged and later-etched normal chip three dimension system-in-package metal circuit board structure according to a fifth embodiment of the present invention;

FIG. 87 is a schematic diagram of a first-packaged and later-etched normal chip three dimension system-in-package metal circuit board structure according to a sixth embodiment of the present invention;

FIG. 88 is a schematic diagram of a first-packaged and later-etched normal chip three dimension system-in-package metal circuit board structure according to a seventh embodiment of the present invention;

FIG. 89 and FIG. 90 are schematic diagrams of a first-packaged and later-etched normal chip three dimension system-in-package metal circuit board structure according to an eighth embodiment of the present invention;

FIG. 91 is a schematic structural diagram of a metal sheet which is subjected to mechanical punch up and down;

FIG. 92 is a schematic structural diagram of a punched strip type metal sheet;

FIG. 93 is a front schematic structural diagram of a lead frame formed by punching;

FIG. 94 is a schematic structural diagram of a metal sheet which is subjected to expose and develop to form a window by chemical etching;

FIG. 95 is a front schematic structural diagram of a lead frame which is formed by chemical etching;

FIG. 96 is a schematic structural diagram of a lead frame which may be used in a QFN package and a molding volume shrunk package;

FIG. 97 is a schematic structural diagram of a pre-molded molding material type lead frame which may be used in QFN package, a molding volume shrunk package and a copper wire bonding package;

FIG. 98 is a cross sectional view of a vertically extended metal region which is formed by extruding tools up and down;

FIG. 99 is a cross sectional view of crack, breakage and warpage generated in the vertical extended metal region metal region which is formed by extruding tools up and down;

FIG. 100 is cross sectional schematic structural diagram of a difficulty to embedded an object in the case where a length of the extended metal region formed by extruding tools up and down is less than 80% of the thickness of the lead frame;

FIG. 101 is a cross sectional schematic structural diagram of non-uniform and flat unflatness of an etching depth;

FIG. 102 is a schematic structural diagram of a thermal performance system-in-package metal lead frame; and

FIG. 103 and FIG. 104 are schematic structural diagrams of a three dimension metal circuit substrate applied to a multiple-chip module (MCM) package.

In the drawings:
metal substrate frame 1
die pad 2
lead 3
conductive pillar 4
chip 5
metal wire 6
anti-oxidizing layer or coating organic solderability preservative 7
molding material or epoxy resin 8
high conductivity metal layer 9
solder mask or photosensitive non-conductive adhesive material 10
passive device 11
electrostatic discharge coil 12
second chip 13
second conductive pillar 14
conductive material 15

### DETAILED DESCRIPTION

A first-packaged and later-etched normal chip three dimension system-in-package metal circuit board structure and a processing method for manufacturing the same provided in the present invention are described below.

### First Embodiment: a Single Wiring Layer, a Single Normally Mounted Chip and a Lap Lead (1)

Referring to FIG. 19, which is a first-packaged and later-etched normal chip three dimension system-in-package metal circuit board structure provided in the present invention, and the structure includes: a metal substrate frame 1; a die pad 2 and a lead 3 provided in the metal substrate frame 1; a conductive pillar 4 provided on a top surface of the lead 3; a chip 5 is mounted normally on a top surface of the die pad 2 by a conductive or non-conductive adhesive material; a metal wire 6 via which a top surface of the chip 5 is connected to a top surface of the lead 3; a molding material or epoxy resin 8 with which a periphery region of the die pad 2, the lead 3, the conductive pillar 4, the chip 5 and the metal wire 6 is encapsulated, with the molding material or epoxy resin 8 being flushed with a top of the conductive pillar 4; and an anti-oxidizing layer or an organic solderability preservative coating 7 is provided on the surface of the metal substrate frame 1, the die pad 2, the lead 3 and the conductive pillar 4 exposed from the molding material or epoxy resin 8.

A processing method for manufacturing a first-packaged and later-etched normal chip three dimension system-in-package metal circuit board structure is described as follows.

Step 1: providing a metal substrate.

Referring to FIG. 1, the metal substrate having suitable thickness is provided the metal substrate may made from copper material, iron material, zinc plating material, stainless steel material, aluminum material or metallic or nonmetallic material which may achieve conductive function. The thickness of the metal substrate may be chosen depending on product properties.

Step 2: pre-plating the surface of the metal substrate with a copper material.

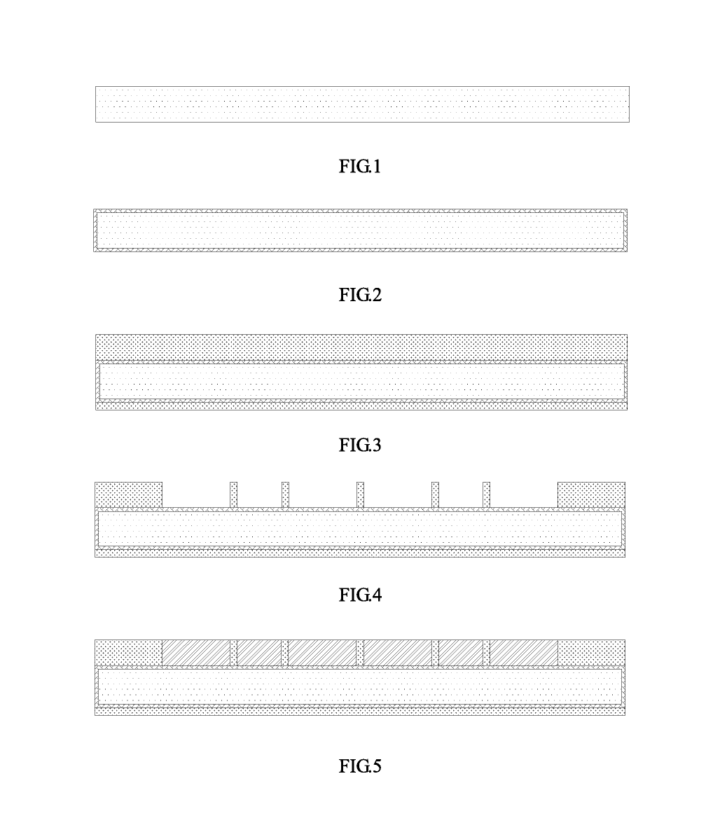

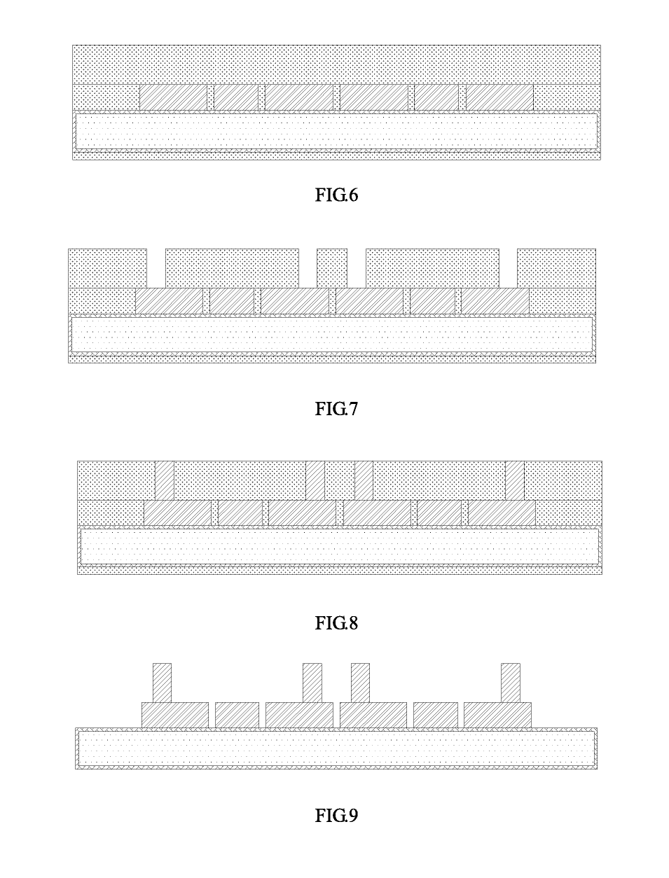

Referring to FIG. 2, the surface of the metal substrate is plated with a layer of copper material. The copper layer has a thickness of 2 μm to 10 μm, which may also be thinned or thickened depending on a function requirement. The plating may be electrolytic plating, and chemical deposition may also be adopted.

Step 3: applying a photoresist film.

Referring to FIG. 3, a top surface and a bottom surface of the metal substrate which have been pre-plated with the copper material in step 2 are respectively pasted with the photoresist film which can be exposed and developed, in order to manufacture a metal wiring pattern later. The photoresist film may be a dry-type photoresist film or a wet-type photoresist film.

Step 4: removing a part of the photoresist film on the top surface of the metal substrate.

Referring to FIG. 4, the top surface of the metal substrate which has been pasted with the photoresist film in step 3 is exposed and developed with a pattern using an exposure and development equipment, and the part of the photoresist film in the pattern is removed, so as to expose a region of the top surface of the metal substrate to be plated with a metal wiring layer later.

Step 5: plating with the metal wiring layer.

Referring to FIG. 5, the region of the top surface of the metal substrate from which the part of the photoresist film has been removed in step 4 is plated with the metal wiring layer, so that a die pad and a lead are formed on the top surface of the metal substrate. The metal wiring layer may be made from copper, aluminum, nickel, silver, gold, copper-silver, nickel-gold, nickel-palladium-gold or the like. The metal wiring layer has a thickness of 5 μm to 20 μm. The metal material for plating can be selected depending on actual application. The plated thickness may be varied depending on product properties. The plating may be electrolytic plating, and chemical deposition may also be adopted.

Step 6: applying a photoresist film.

Referring to 6, the top surface of the metal substrate which has been plated with the metal wiring layer in step 5 is pasted with the photoresist film which can be exposed and developed, in order to manufacture a conductive pillar later. The photoresist film may be a dry-type photoresist film or a wet-type photoresist film.

Step 7: removing a part of the photoresist film on the top surface of the metal substrate.

Referring to FIG. 7, the top surface of the metal substrate which has been pasted with the photoresist film in step 6 is exposed and developed with a pattern using an exposure and development equipment, and the part of the photoresist film in a pattern is removed, so as to expose a region of the top surface of the metal substrate to be plated with a conductive pillar later.

Step 8: plating with the conductive pillar.

Referring to FIG. 8, the region of the top surface of the metal substrate from which a part of the photoresist film has been removed in step 7 is plated with the conductive pillar. The conductive pillar may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 9: removing the photoresist film.

Referring to FIG. 9, the photoresist film on the surface of the metal substrate is removed. The photoresist film may be removed by softening with chemicals and cleaning with high pressure water.

Step 10: bonding die.

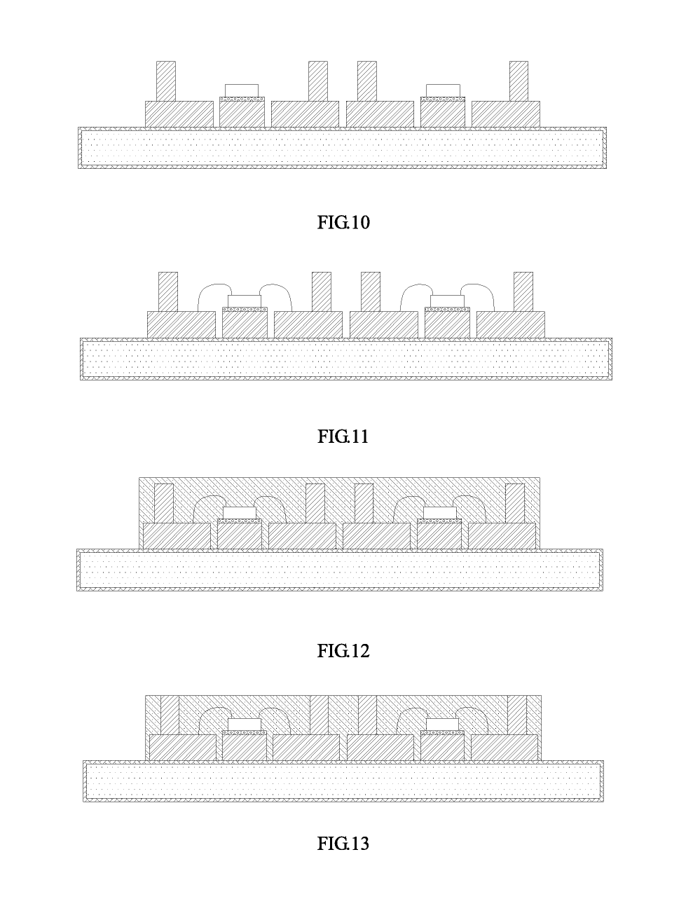

Referring to FIG. 10, a chip is embedded in a top surface of the die pad formed in step 5 by coating with a conductive or non-conductive adhesive material.

Step 11: bonding a metal wire.

Referring to FIG. 11, the metal wire is bonded between a top surface of the chip and the lead formed in step 5.

Step 12: molding with an epoxy resin.

Referring to FIG. 12, the molding with the epoxy resin for protecting is performed on the top surface of the metal substrate after the bonding die and the metal wire bonding have been performed. The epoxy resin material may be selected to be an epoxy resin with or without filler depending on product properties.

Step 13: grinding a surface of the epoxy resin.

Referring to FIG. 13, the surface of the epoxy resin is ground after the molding with the epoxy resin has been performed in step 12.

Step 14: applying a photoresist film.

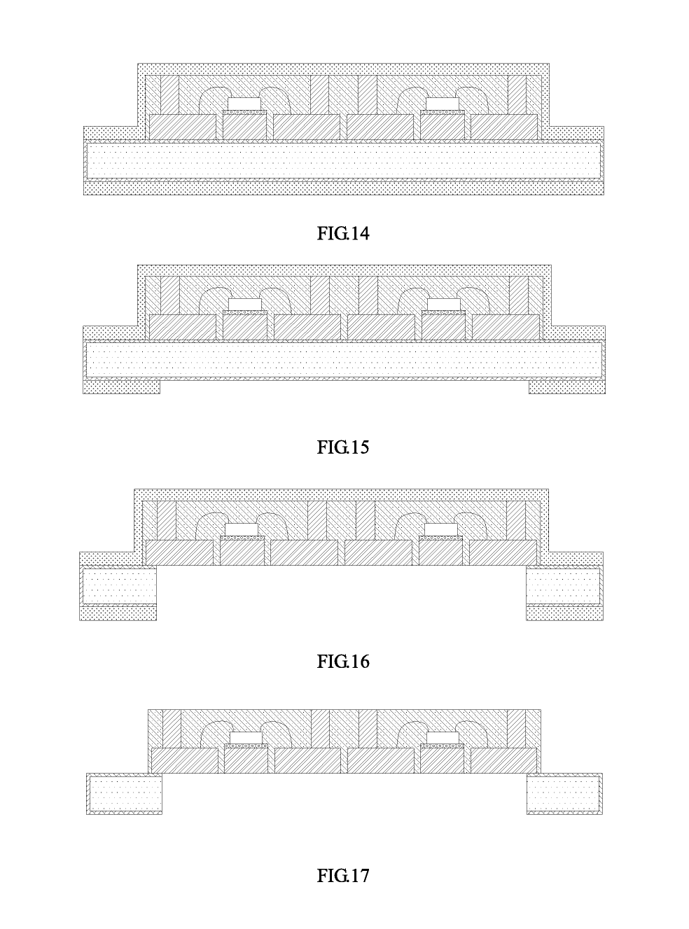

Referring to FIG. 14, the top surface and the bottom surface of the metal substrate are pasted with the photoresist film adapted to expose and develop after the surface of the epoxy resin has been ground in step 13.

Step 15: removing a part of the photoresist film on the bottom surface of the metal substrate.

Referring to FIG. 15, the bottom surface of the metal substrate, which has been pasted with the photoresist film in step 14, is exposed and developed with a pattern using an exposure and development equipment, and the part of the photoresist film in the pattern is removed, so as to expose a region of the bottom surface of the metal substrate to be etched later.

Step 16: etching.

Referring to FIG. 16, chemical etching is performed in the region of the bottom surface of the metal substrate from which the part of the photoresist film has been removed in step 15.

Step 17: removing the photoresist film.

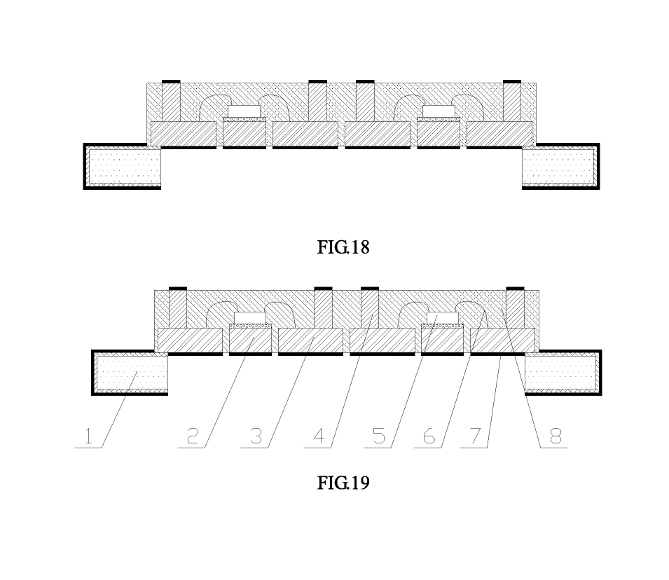

Referring to FIG. 17, the photoresist film on the surface of the metal substrate is removed. The photoresist film is removed by softening with chemicals and cleaning with high pressure water.

Step 18: plating with an anti-oxidizing metal layer or coating with an organic solderability preservative (OSP).

Referring to FIG. 18, an exposed metal surface of the metal substrate surface from which the photoresist film has been removed in step 17 is plated with the anti-oxidizing metal layer, such as gold, nickel, nickel-palladium-gold or tin, or is coated with the organic solderability preservative (OSP).

### Second Embodiment: a Single Wiring Layer, a Single Normally Mounted Chip and a Lap Lead (2)

Referring to FIG. 41, which is a first-packaged and later-etched normal chip three dimension system-in-package metal circuit board structure provided in the present invention, and the structure includes: a metal substrate frame 1; a die pad 2 and a lead 3 provided in the metal substrate frame 1; a conductive pillar 4 provided on the top surface of the lead 3, a chip 5 is mounted normally on the top surface of the die pad 2 by a conductive or non-conductive adhesive material; a metal wire 6 via which the top surface of the chip 5 is connected to the top surface of the lead 3; a molding material or epoxy resin 8 with which a periphery region of the die pad 2, the lead 3, the conductive pillar 4, the chip 5 and the metal wire 6 is encapsulated, with the molding material or epoxy resin 8 being flushed with a top of the conductive pillar 4; a high conductivity metal layer 9 provided on the bottom surface of the die pad 2 and the lead 3; a solder mask or photosensitive non-conductive adhesive 10 filled between the high conductivity metal layers 9; an anti-oxidizing layer or coating organic solderability preservative 7 provided on the surface of the metal substrate frame 1, the conductive pillar 4 and the high conductivity metal layer 9 exposed from the molding material or epoxy resin 8 and the solder mask or photosensitive non-conductive adhesive material 10.

The differences between the second embodiment and the first embodiment are that: the conductive pillar 4 according to the second embodiment is used as an inner lead actually, and the subsequent molding progress is performed on the top surface of the metal substrate frame; while the conductive pillar 4 according to the first embodiment is used as an outer lead actually, the subsequent molding progress is performed on the bottom surface of the metal substrate frame.

A processing method for manufacturing a first-packaged and later-etched normal chip three dimension system-in-package metal circuit board structure is described as follows.

Step 1: providing a metal substrate.

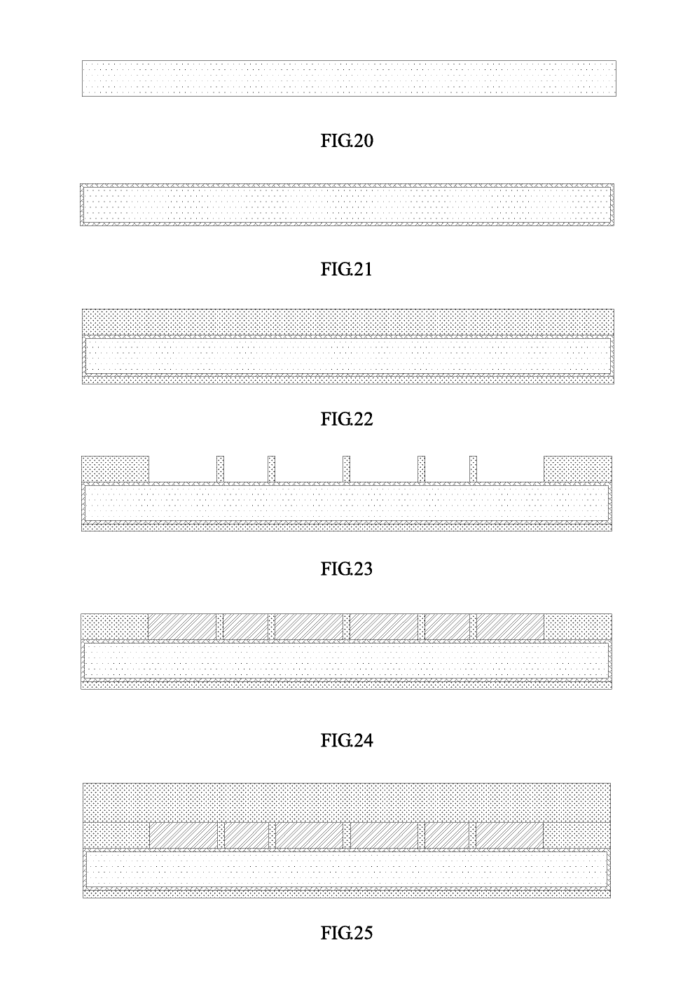

Referring to FIG. 20, the metal substrate having suitable thickness is provided. The metal substrate may be made from copper material, iron material, zinc plating material, stainless steel material, aluminum material, metallic material which may achieve conductive function or the like. The thickness of the metal substrate may be chosen depending on product properties.

Step 2: pre-plating the surface of the metal substrate with a copper material.

Referring to FIG. 21, the surface of the metal substrate is plated with a layer of copper material. The copper layer has a thickness of 2 μm to 10 μm, which may also be thinned or thickened depending on a function requirement. The plating may be electrolytic plating, and chemical deposition may also be adopted.

Step 3: applying a photoresist film.

Referring to FIG. 22, a top surface and a bottom surface of the metal substrate which have been pre-plated with the copper material in step 2 are respectively pasted with the photoresist film which can be exposed and developed, in order to manufacture a metal wiring pattern later. The photoresist film may be a dry-type photoresist film or a wet-type photoresist film.

Step 4: removing a part of the photoresist film on the top surface of the metal substrate.

Referring to FIG. 23, the top surface of the metal substrate which has been pasted with the photoresist film in step 3 is exposed and developed with a pattern using an exposure and development equipment, and the part of the photoresist film in the pattern is removed, so as to expose an region of the top surface of the metal substrate to be plated with a metal wiring layer later.

Step 5: plating with the metal wiring layer.

Referring to FIG. 24, the region of the top surface of the metal substrate from which the part of the photoresist film has been removed in step 4 is plated with the metal wiring layer, so that a die pad and a lead are formed on the top surface of the metal substrate. The metal wiring layer may be made from copper, aluminum, nickel, silver, gold, copper-silver, nickel-gold, nickel-palladium-gold, metallic materials which may achieve a conductive function or the like. The metal wiring layer has a thickness of 5 μm to 20 μm. The metal material for plating can be selected depending on actual applications. The plated thickness may be varied depending on product properties. The plating may be electrolytic plating, and chemical deposition may also be adopted.

Step 6: applying a photoresist film.

Referring to 25, the top surface of the metal substrate which has been plated with the metal wiring layer in step 5 is pasted with the photoresist film which can be exposed and developed, in order to manufacture a conductive pillar later. The photoresist film may be a dry-type photoresist film or a wet-type photoresist film.

Step 7: removing a part of the photoresist film on the top surface of the metal substrate.

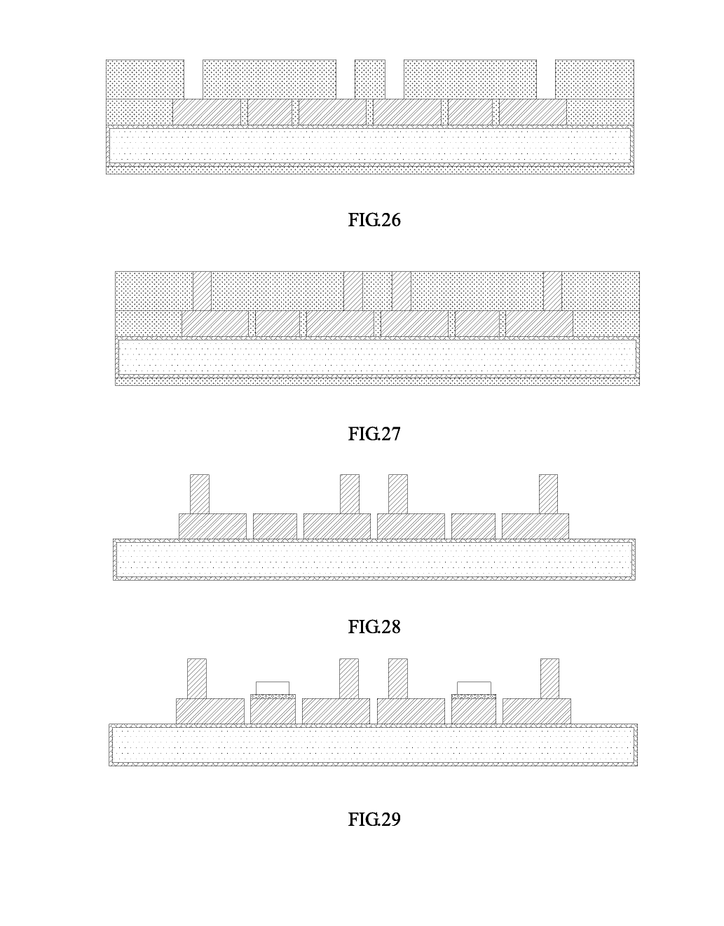

Referring to FIG. 26, the top surface of the metal substrate which has been pasted with the photoresist film in step 6 is exposed and developed with a pattern using an exposure and development equipment, and the part of the photoresist film in a pattern is removed, so as to expose a region of the top surface of the metal substrate to be plated with a conductive pillar later.

Step 8: plating with the conductive pillar.

Referring to FIG. 27, the region of the top surface of the metal substrate from which a part of the photoresist film has been removed in step 7 is plated with the conductive pillar. The conductive pillar may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 9: removing the photoresist film.

Referring to FIG. 28, the photoresist film on the surface of the metal substrate is removed. The photoresist film may be removed by softening with chemicals and cleaning with high pressure water.

Step 10: bonding die.

Referring to FIG. 29, a chip is embedded in a top surface of the die pad formed in step 5 by coating with a conductive or non-conductive adhesive material.

Step 11: bonding a metal wire.

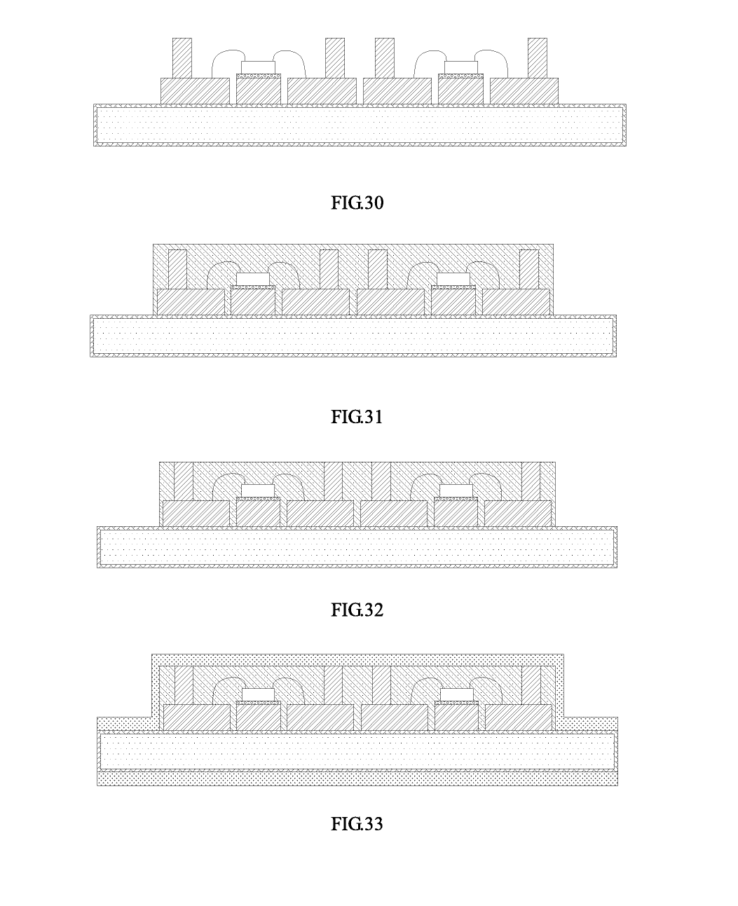

Referring to FIG. 30, the metal wire is bonded between a top surface of the chip and the lead formed in step 5.

Step 12: molding with an epoxy resin.

Referring to FIG. 31, the molding with the epoxy resin for protecting is performed on the top surface of the metal substrate after the bonding die and the metal wire bonding have been performed. The epoxy resin material may be selected to be an epoxy resin with or without filler depending on product properties.

Step 13: grinding a surface of the epoxy resin.

Referring to FIG. 32, the surface of the epoxy resin is ground after the molding with the epoxy resin has been performed in step 12.

Step 14: applying a photoresist film.

Referring to FIG. 33, the top surface and the bottom surface of the metal substrate are pasted with the photoresist film which can be exposed and developed after the surface of the epoxy resin has been ground in step 13.

Step 15: removing a part of the photoresist film on the bottom surface of the metal substrate.

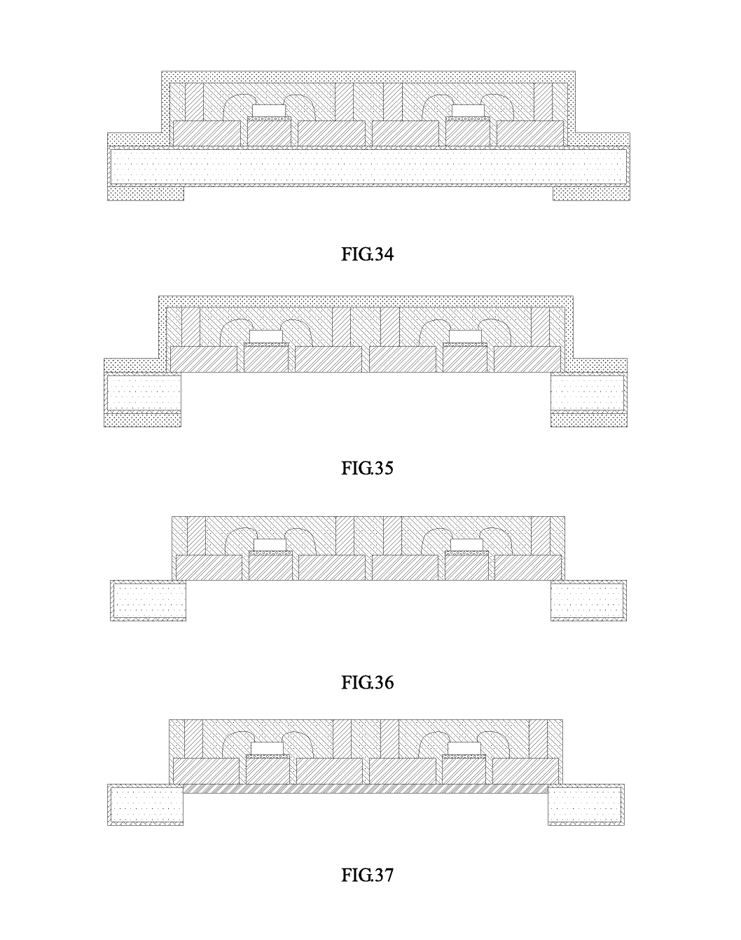

Referring to FIG. 34, the bottom surface of the metal substrate, which has been pasted with the photoresist film in step 14, is exposed and developed with a pattern using an exposure and development equipment, and the part of the photoresist film in the pattern is removed, so as to expose a region of the bottom surface of the metal substrate to be etched later.

Step 16: etching.

Referring to FIG. 35, chemical etching is performed in the region of the bottom surface of the metal substrate from which the part of the photoresist film has been removed in step 15.

Step 17: removing the photoresist film.

Referring to FIG. 36, the photoresist film on the surface of the metal substrate is removed. The photoresist film is removed by softening with chemicals and cleaning with high pressure water.

Step 18: coating the bottom surface of the metal substrate with a solder mask or photosensitive non-conductive adhesive material.

Referring to FIG. 37, the bottom surface of the metal substrate from which the photoresist film has been removed in step 17 is coated with the solder mask or photosensitive non-conductive adhesive material.

Step 19: exposing and developing to form a window.

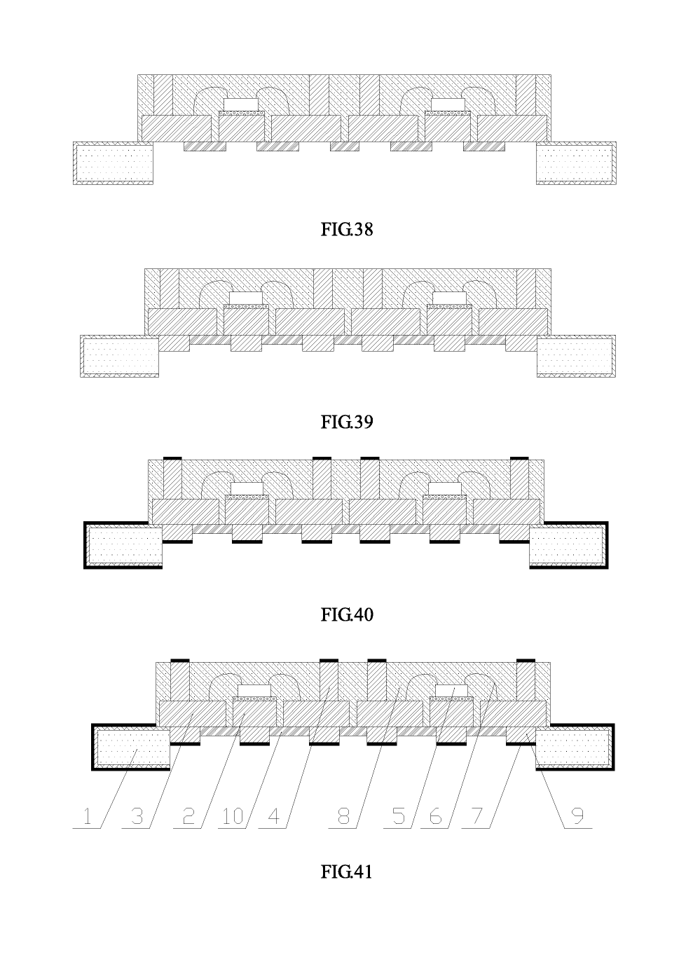

Referring to FIG. 38, the solder mask or photosensitive non-conductive adhesive material with which the bottom surface of the metal substrate is coated is exposed and developed using an exposure and development equipment to form the window, so as to expose a region of the bottom surface of the metal substrate to be plated with a high conductivity metal layer later.

Step 20: plating with the high conductivity metal layer.

Referring to FIG. 39, a region of the window formed in the solder mask or photosensitive non-conductive adhesive material on the bottom surface of the metal substrate in the Step 19 is plated with the high conductivity metal layer.

Step 21: plating with an anti-oxidizing metal layer or coating with an organic solderability preservative (OSP).

Referring to FIG. 40, an exposed metal surface of the metal substrate surface from which the photoresist film has been removed is plated with the anti-oxidizing metal layer, such as gold, nickel, nickel-palladium-gold or tin, or coated with the organic solderability preservative (OSP).

### Third Embodiment: Multiple Wiring Layers, a Single Normally Mounted Chip and a Lap Lead

Referring to FIG. 84, which is a first-packaged and later-etched normal chip three dimension system-in-package metal circuit board structure provided in the present invention, and the structure includes: a metal substrate frame 1; a die pad 2 and a lead 3 provided in the metal substrate frame 1; a conductive pillar 4 provided on the top surface of the lead 3; a chip 5 is mounted normally on the top surface of the die pad 2 by a conductive or non-conductive adhesive material; a metal wire 6 via which the top surface of the chip 5 is connected to the top surface of the lead 3; a molding material or epoxy resin 8 with which a periphery region of the die pad 2, the lead 3, the conductive pillar 4, the chip 5 and the metal wire 6 are encapsulated, with the molding material or epoxy resin 8 being flushed with a top of the conductive pillar 4; an anti-oxidizing layer or coating organic solderability preservative 7 provided on the surface of the metal substrate frame 1, the die pad 2, the lead 3 and the conductive pillar 4 exposed from the molding material or epoxy resin 8.

The third embodiment differs from the first embodiment in that the die pad 2 and the lead 3 are both formed of the multiple metal wiring layers, and the metal wiring layers are connected with each other via a conductive pillar.

A processing method for manufacturing a first-packaged and later-etched normal chip three dimension system-in-package metal circuit board structure is described as follows.

Step 1: providing a metal substrate.

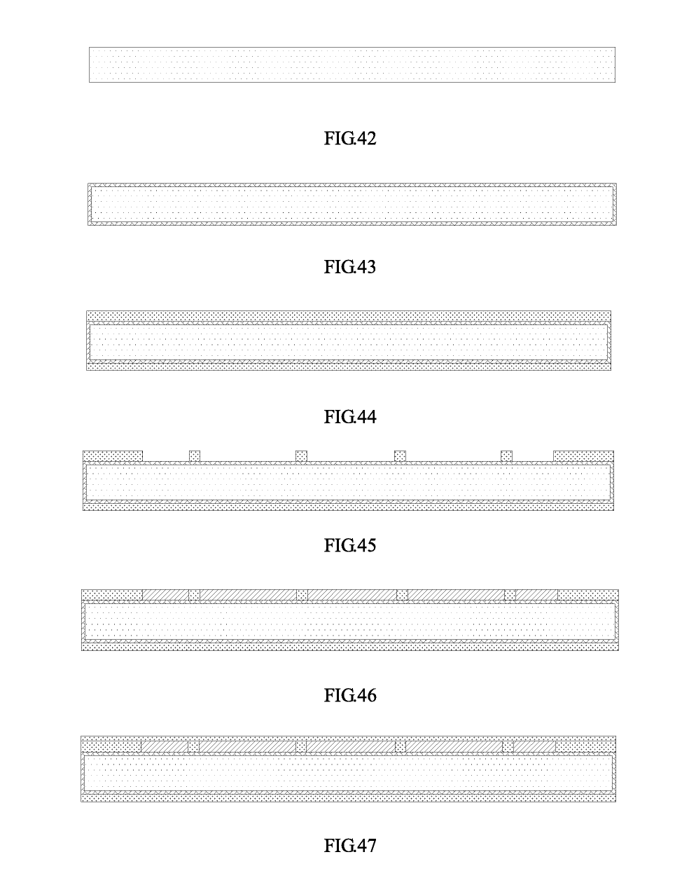

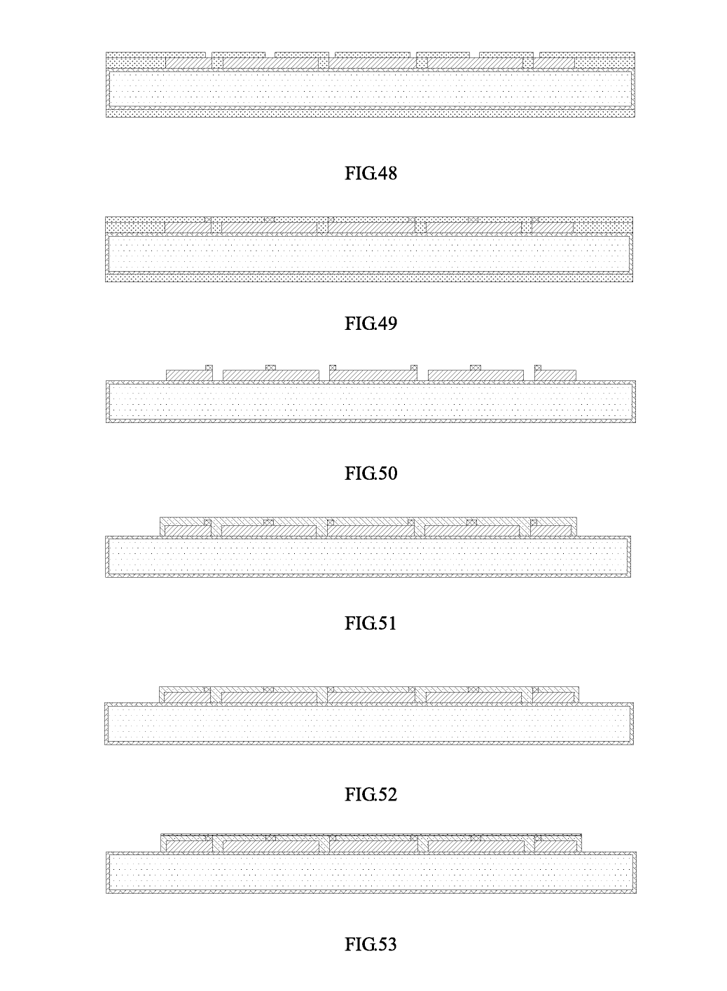

Referring to FIG. 42, the metal substrate having suitable thickness is provided. The metal substrate may be made from copper material, iron material, zinc plating material, stainless steel material, aluminum material or metallic or nonmetallic material which may achieve a conductive function. The thickness of the metal substrate may be chosen depending on product properties.

Step 2: pre-plating the surface of the metal substrate with a copper material.

Referring to FIG. 43, the surface of the metal substrate is pre-plated with a layer of copper material. The copper layer has a thickness of 2 μm to 10 μm, which may also be thinned or thickened depending on a function requirement. The plating may be electrolytic plating, and chemical deposition may also be adopted.

Step 3: applying a photoresist film.

Referring to FIG. 44, a top surface and a bottom surface of the metal substrate which have been pre-plated with the copper material in step 2 are respectively pasted with the photoresist film which can be exposed and developed, in order to manufacture a metal wiring pattern later. The photoresist film may be a dry-type photoresist film or a wet-type photoresist film.

Step 4: removing a part of the photoresist film on the top surface of the metal substrate.

Referring to FIG. 45, the top surface of the metal substrate which has been pasted with the photoresist film in step 3 is exposed and developed with a pattern using an exposure and development equipment, and the part of the photoresist film in the pattern is removed, so as to expose a region of the top surface of the metal substrate to be plated with a first metal wiring layer later.

Step 5: plating with the first metal wiring layer.

Referring to FIG. 46, the region of the top surface of the metal substrate from which the part of the photoresist film has been removed in step 4 is plated with the first metal wiring layer. The metal wiring layer may be made from copper, aluminum, nickel, silver, gold, copper-silver, nickel-gold, nickel-palladium-gold or the like. The plating may be electrolytic plating, and chemical deposition may also be adopted.

Step 6: applying a photoresist film.

Referring to 47, the top surface of the metal substrate which has been plated with the first metal wiring layer in step 5 is pasted with the photoresist film which can be exposed and developed, in order to manufacture a metal wiring pattern later. The photoresist film may be a dry-type photoresist film or a wet-type photoresist film.

Step 7: removing part of the photoresist film on the top surface of the metal substrate.

Referring to FIG. 48, the top surface of the metal substrate which has been pasted with the photoresist film in step 6 is exposed and developed with a pattern using an exposure and development equipment, and the part of the photoresist film in a pattern is removed, so as to expose a region of the top surface of the metal substrate to be plated with a second metal wiring layer later.

Step 8: plating with the second metal wiring layer.

Referring to FIG. 49, the region of the top surface of the metal substrate from which a part of the photoresist film has been removed in step 7 is plated with the second wiring layer serving as a conductive pillar for connecting the first metal wiring layer to a third metal wiring layer. The second metal wiring layer may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 9: removing the photoresist film.

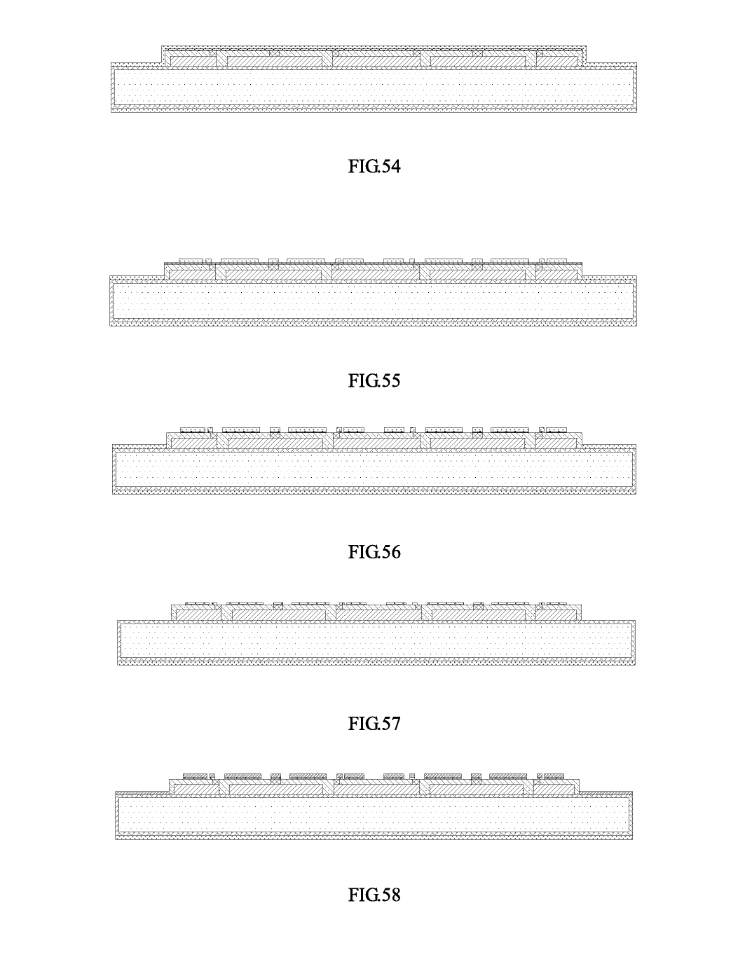

Referring to FIG. 50, the photoresist film on the surface of the metal substrate is removed. The photoresist film may be removed by softening with chemicals and cleaning with high pressure water.

Step 10: applying a non-conductive adhesive film.

Referring to FIG. 51, a region of the top surface of the metal substrate in which the wiring layer is provided is pasted with a layer of non-conductive adhesive film, in order to insulate the first metal wiring layer from the third metal wiring layer. The non-conductive adhesive film may be pasted with by a conventional rolling machine, or in a vacuum environment to prevent air residual during the pasting. The non-conductive adhesive film is mainly a pasting type non-conductive adhesive film made from thermosetting epoxy resin. And the epoxy resin may be an epoxy resin with or without filler depending on product properties.

Step 11: grinding a surface of the non-conductive adhesive film.

Referring to FIG. 52, the surface of the non-conductive adhesive film is ground after the applying non-conductive adhesive film has been performed in step 10, in order to expose the second metal wiring layer, maintain the flatness of the non-conductive adhesive film and the second metal wiring layer and control the thickness of the non-conductive adhesive film.

Step 12: performing metallization pre-treatment on a surface of the non-conductive adhesive film.

Referring to FIG. 53, the metallization pre-treatment is performed on the surface of the non-conductive adhesive film, such that a layer of metalized polymer material is adhered onto the surface of the non-conductive adhesive film in order to provide a surface serving as a catalytic converter for plating with a metallic material later, or roughening treatment is performed on the surface of the non-conductive adhesive film. The metalized polymer material may be adhered by spraying, plasma oscillation, surface roughening, or the like, and then it is dried.

Step 13: applying a photoresist film.

Referring to FIG. 54, the top surface and the bottom surface of the metal substrate are pasted with the photoresist film which can be exposed and developed after the metallization pre-treatment has been performed in step 12, in order to manufacture a metal wiring pattern later. The photoresist film may be a dry-type photoresist film or a wet-type photoresist film.

Step 14: removing a part of the photoresist film on the top surface of the metal substrate.

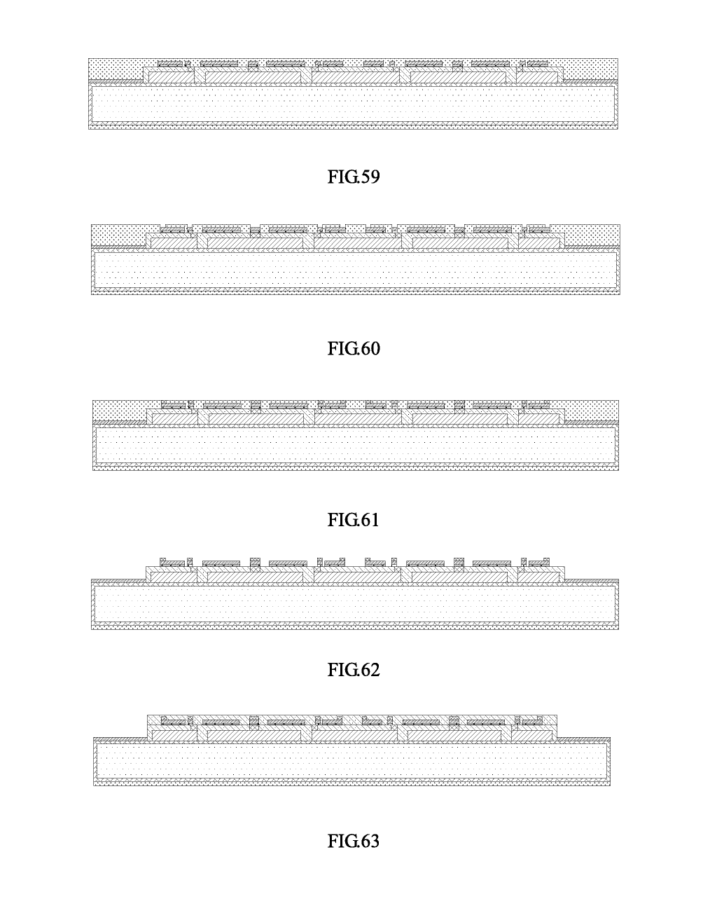

Referring to FIG. 55, the top surface of the metal substrate which has been pasted with the photoresist film in step 13, is exposed and developed with a pattern using an exposure and development equipment, and the part of the photoresist film in pattern is removed, so as to expose a region of the top surface of the metal substrate to be etched later.

Step 15: etching.

Referring to FIG. 56, the region of the top surface of the metal substrate from which the part of the photoresist film has been removed in step 14 is etched, in order to etch and remove the metallization pre-treatment region in which plating with a third metal wiring layer is not needed to be performed later using the etching technology. The processing method for etching may be an etching process using copper chloride or iron chloride.

Step 16: removing the photoresist film.

Referring to FIG. 57, the photoresist film on the top surface of the metal substrate is removed. The photoresist film may be removed by softening with chemicals and cleaning with high pressure water.

Step 17: plating with the third metal wiring layer.

Referring to FIG. 58, the remaining metallization pre-treatment region of the top surface of the metal substrate on which the etching has been performed in step 15 is plated with the third metal wiring layer. The third metal wiring layer may be made from copper, aluminum, nickel, silver, gold, copper-silver, nickel-gold, nickel-palladium-gold or the like. The plating may be electrolytic plating, and chemical deposition may also be adopted.

Step 18: applying a photoresist film.

Referring to FIG. 59, the top surface of the metal substrate which has been plated with the third metal wiring layer in step 17 is pasted with the photoresist film adapted to expose and develop, in order to manufacture a metal wiring pattern later. The photoresist film may be a dry-type photoresist film or a wet-type photoresist film.

Step 19: removing a part of the photoresist film on the top surface of the metal substrate.

Referring to FIG. 60, the top surface of the metal substrate which has been pasted with the photoresist film in step 18 is exposed and developed with a pattern using an exposure and development equipment, and the part of the photoresist film in the pattern is removed, so as to expose a region of the top surface of the metal substrate to be plated with a fourth metal wiring layer.

Step 20: plating with the fourth metal wiring layer.

Referring to FIG. 61, the region of the top surface of the metal substrate from which a part of the photoresist film has been removed in step 19 is plated with the fourth metal wiring layer serving as a conductive pillar for connecting the third metal wiring layer to the fifth metal wiring layer. The fourth metal wiring layer may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 21: removing the photoresist film.

Referring to FIG. 62, the photoresist film on the top surface of the metal substrate is removed. The photoresist film may be removed by softening with chemicals and cleaning with high pressure water.

Step 22: applying a non-conductive adhesive film.

Referring to FIG. 63, a region of the top surface of the metal substrate in which the wiring layer is provided is pasted with a layer of non-conductive adhesive film, in order to insulate the third metal wiring layer from the fifth metal wiring layer. The non-conductive adhesive film may be pasted with by a conventional rolling machine, or in a vacuum environment to prevent air residual during the pasting. The non-conductive adhesive film is mainly a pasting type non-conductive adhesive film made from thermosetting epoxy resin. And the epoxy resin may be an epoxy resin with or without a filled material depending on product properties.

Step 23: grinding a surface of the non-conductive adhesive film.

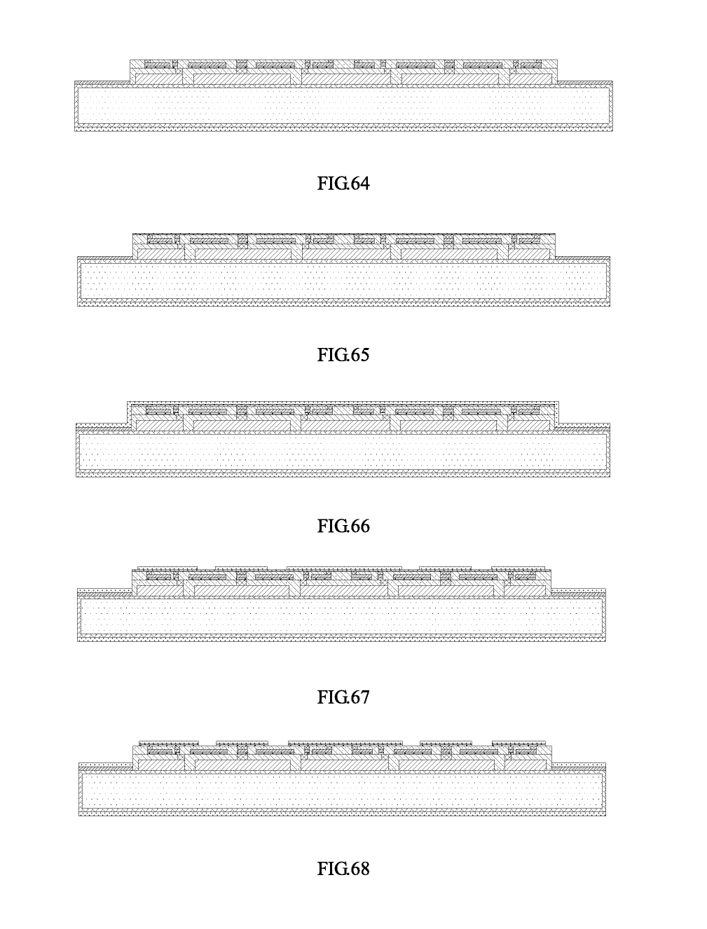

Referring to FIG. 64, a surface of the non-conductive adhesive film is ground after the applying the non-conductive adhesive film has been performed in step 22, in order to expose the fourth metal wiring layer, maintain the flatness of the non-conductive adhesive film and the fourth metal wiring layer and control the thickness of the non-conductive adhesive film.

Step 24: performing metallization pre-treatment on a surface of the non-conductive adhesive film.

Referring to FIG. 65, the metallization pre-treatment is performed on the surface of the non-conductive adhesive film, such that a layer of metalized polymer material is adhered onto the surface of the non-conductive adhesive film in order to provide a surface serving as a catalytic converter for plating with a metallic material later, or roughening treatment is performed on the surface of the non-conductive adhesive film. The metalized polymer material may be adhered by spraying, plasma oscillation, surface roughening, or the like, and then it is dried.

Step 25: applying a photoresist film.

Referring to FIG. 66, the top surface and the bottom surface of the metal substrate on which the metallization pre-treatment has been performed in step 24 are pasted with the photoresist film which can be exposed and developed, in order to manufacture a metal wiring pattern later. The photoresist film may be a dry-type photoresist film or a wet-type photoresist film.

Step 26: removing a part of the photoresist film on the top surface of the metal substrate.

Referring to FIG. 67, the top surface of the metal substrate which has been pasted with the photoresist film in step 25 is exposed and developed with a pattern using an exposure and development equipment, and the part of the photoresist film in the pattern is removed, so as to expose a region of the top surface of the metal substrate to be etched later.

Step 27: etching.

Referring to FIG. 68, the region of the top surface of the metal substrate from which the part of the photoresist film has been removed in step 26 is etched, in order to etch and remove the metallization pre-treatment region in which plating with a fifth metal wiring layer is not needed to be performed later using the etching technology. The processing method for etching may be an etching process using copper chloride or iron chloride.

Step 28: removing the photoresist film.

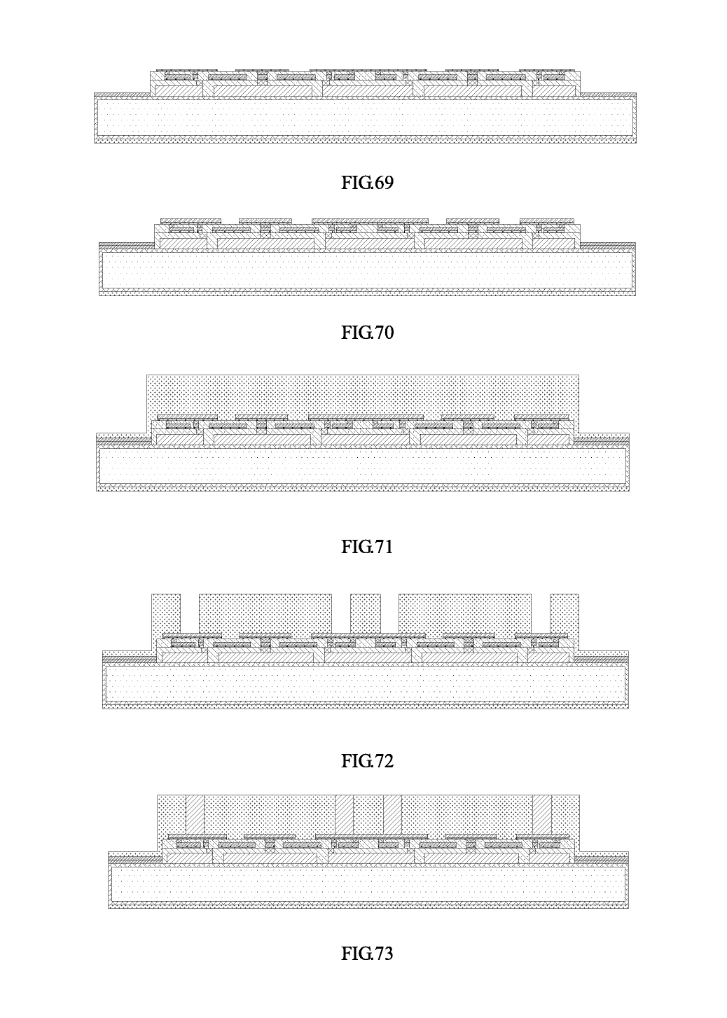

Referring to FIG. 69, the photoresist film on the surface of the metal substrate is removed. The photoresist film may be removed by softening with chemicals and cleaning with high pressure water.

Step 29: plating with the fifth metal wiring layer.

Referring to FIG. 70, the remaining metallization pre-treatment region of the top surface of the metal substrate on which the etching has been performed in step 27 is plated with the fifth metal wiring layer, so that a die pad and a lead are formed on the top surface of the metal substrate. The fifth metal wiring layer may be made from copper, aluminum, nickel, silver, gold, copper-silver, nickel-gold or nickel-palladium-gold. The plating may be electrolytic plating, and chemical deposition may also be adopted.

Step 30: applying a photoresist film.

Referring to FIG. 71, the top surface of the metal substrate which has been plated with the fifth metal wiring layer in step 29 is pasted with the photoresist film which can be exposed and developed, in order to manufacture a conductive pillar later. The photoresist film may be a dry-type photoresist film or a wet-type photoresist film.

Step 31: removing a part of the photoresist film on the top surface of the metal substrate.

Referring to FIG. 72, the top surface of the metal substrate which has been pasted with the photoresist film in step 30 is exposed and developed with a pattern using an exposure and development equipment, and the part of the photoresist film in the pattern is removed, so as to expose a region of the top surface of the metal substrate to be plated with a conductive pillar.

Step 32: plating with the conductive pillar.

Referring to FIG. 73, the region of the top surface of the metal substrate from which the part of the photoresist film has been removed in step 31 is plated with the conductive pillar. The material of the conductive pillar may be made from copper, aluminum, nickel, silver, gold, copper-silver, nickel-gold, nickel-palladium-gold, metallic material which may achieve conductive function or the like. The plating may be electrolytic plating, and chemical deposition may also be adopted.

Step 33: removing the photoresist film.

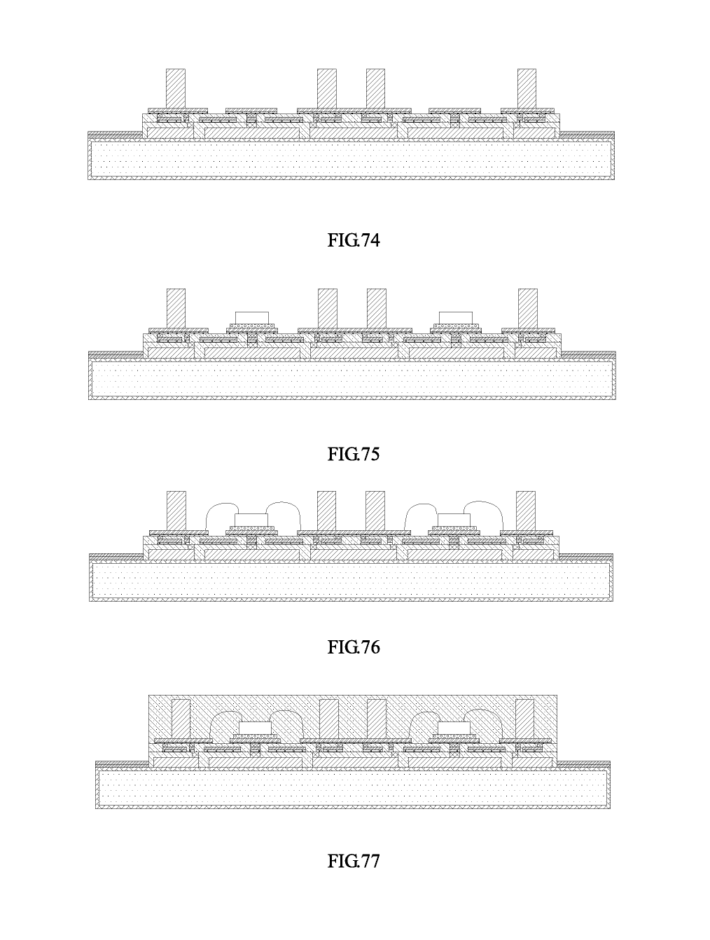

Referring to FIG. 74, the photoresist film on the surface of the metal substrate is removed. The photoresist film may be removed by softening with chemicals and cleaning with high pressure water.

Step 34: bonding die.

Referring to FIG. 75, a chip is embedded in a top surface of the die pad formed in step 29 by coating with a conductive or non-conductive adhesive material.

Step 35: bonding a metal wire.

Referring to FIG. 76, the metal wire is bonded between a top surface of the chip and the lead formed in step 29.

Step 36: molding with epoxy resin.

Referring to FIG. 77, the molding with the epoxy resin for protecting is performed on the top surface of the metal substrate after the bonding die and the metal wire bonding have been performed. The epoxy resin material may be selected to be an epoxy resin with or without filler depending on product properties.

Step 37: grinding a surface of the epoxy resin.

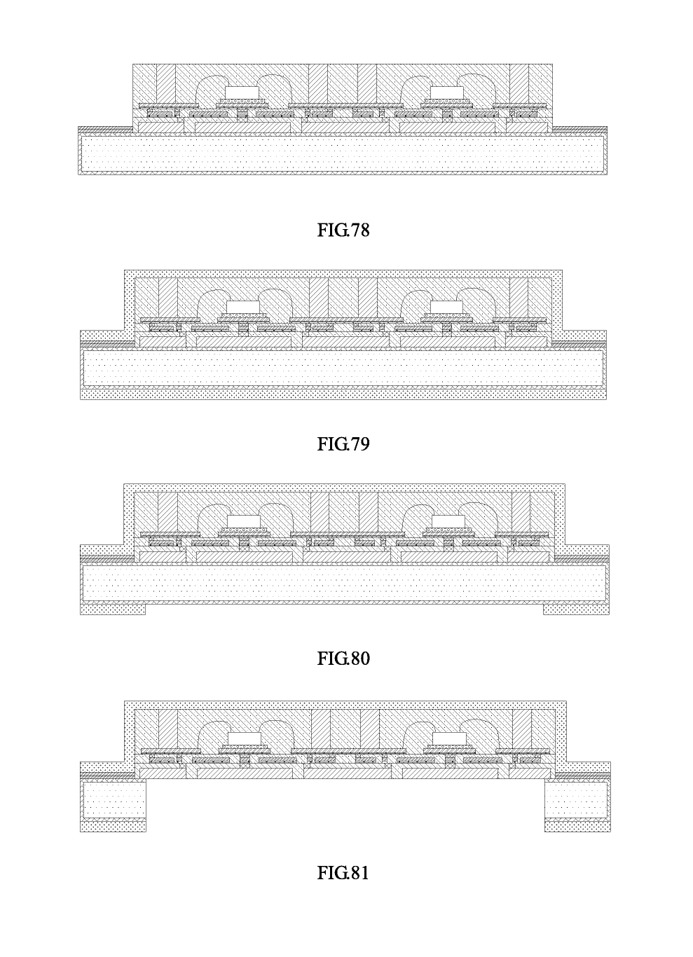

Referring to FIG. 78, the surface of the epoxy resin is ground after the molding with the epoxy resin has been performed in step 36.

Step 38: applying a photoresist film.

Referring to FIG. 79, a top surface and a bottom surface of the metal substrate are pasted with the photoresist film which can be exposed and developed after the surface of the epoxy resin has been ground in step 37.

Step 39: removing a part of the photoresist film on the bottom surface of the metal substrate.

Referring to FIG. 80, the bottom surface of the metal substrate which has been pasted with the photoresist film in step 38 is exposed and developed with a pattern using an exposure and development equipment, and the part of the photoresist film in the pattern is removed, so as to expose a region of the bottom surface of the metal substrate to be etched later.

Step 40: etching.

Referring to FIG. 81, chemical etching is performed in the region of the bottom surface of the metal substrate from which the part of the photoresist film has been removed in step 39.

Step 41: removing the photoresist film.

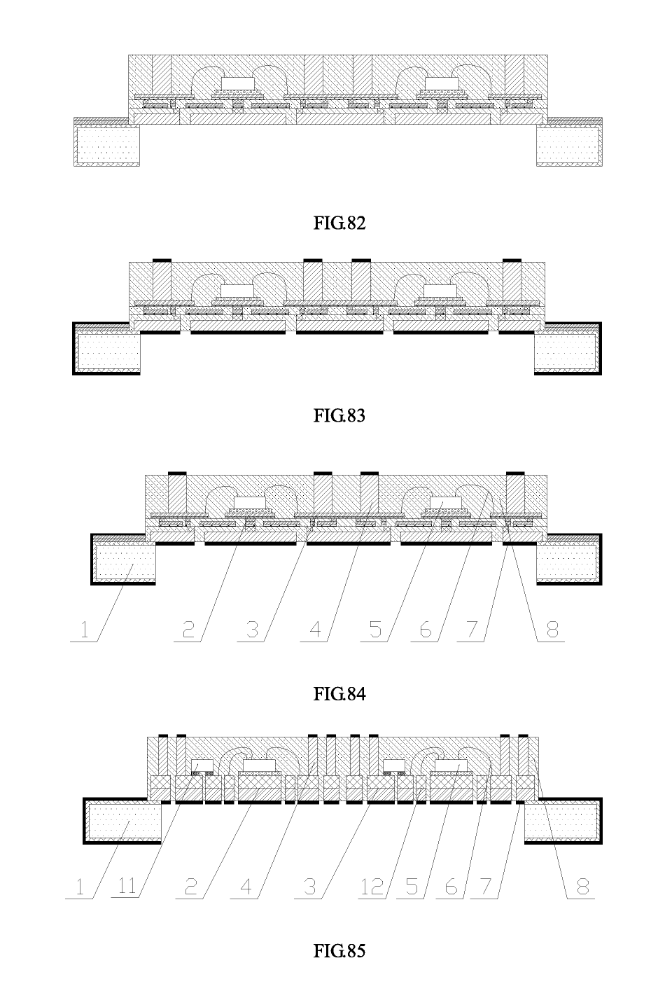

Referring to FIG. 82, the photoresist film on the surface of the metal substrate is removed. The photoresist film may be removed by softening with chemicals and cleaning with high pressure water.

Step 42: plating with an anti-oxidizing metal layer or coating with an organic solderability preservative (OSP).

Referring to FIG. 83, the exposed metal surface of the metal substrate surface from which the photoresist film has been removed in step 41 is plated with the anti-oxidizing metal layer, such as gold, nickel, nickel-palladium-gold or tin, or is coated with the organic solderability preservative (OSP).

### Fourth Embodiment: a Single Normally Mounted Chip, Multiple Lap Leads, a Passive Device and an Electrostatic Discharge Coil

Referring to FIG. 85, the fourth embodiment differs from the first embodiment in that multi-turn conductive pillar 4 are provided; a passive device 11 is connected across a top surface of the leads 3; the electrostatic discharge coil 12 is provided between the die pad 2 and the lead 3; and a top surface of the chip 5 is connected to a top surface of the electrostatic discharge coil 12 via a metal wire 6.

### Fifth Embodiment: Multiple Chips Provided in a Plane

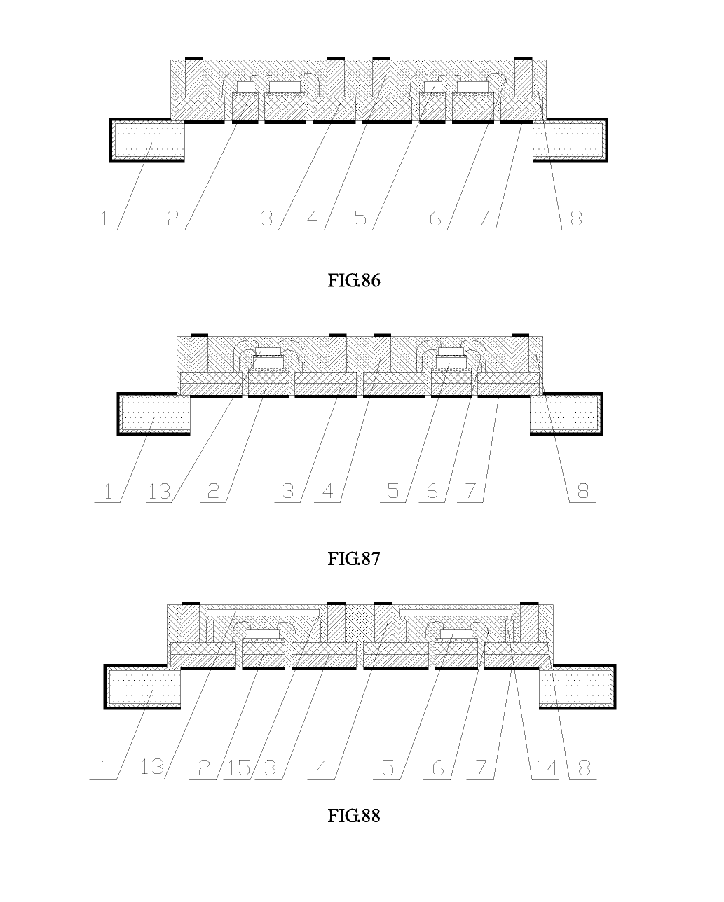

Referring to FIG. 86, the fifth embodiment differs from the first embodiment in that a plurality of die pads 2 are provided; a chip 5 is provided on each of the plurality of die pad 2; and the top surfaces of the chips 5 are connected via metal wires 6.

### Sixth Embodiment: Multiple Chips Stack with a Normal Chip Being Normally Mounted on Another Normal Chip

Referring to FIG. 87, the sixth embodiment differs from the first embodiment in that a second chip 13 is mounted normally on the top surface of the chip 5; and the second chip 13 is connected to the lead 3 via a metal wire 6.

### Seventh Embodiment: Multiple Chips Stack with a Chip Being Normally Mounted on a Flip-Chip

Referring to FIG. 88, the seventh embodiment differs from the first embodiment in that a second conductive pillar 14 is provided on the top surface of the lead 3; a second chip 13 is flipped on the second conductive pillar 14 by a conductive material 15; the second chip 13 is located above the chip 5; and the second conductive pillar 14 and the second chip 13 are located inside the molding material 8.

The second chip 13 may be replaced by passive device 11.

### Eighth Ebodiment: a Single Normally Mounted Chip without a Die Pad

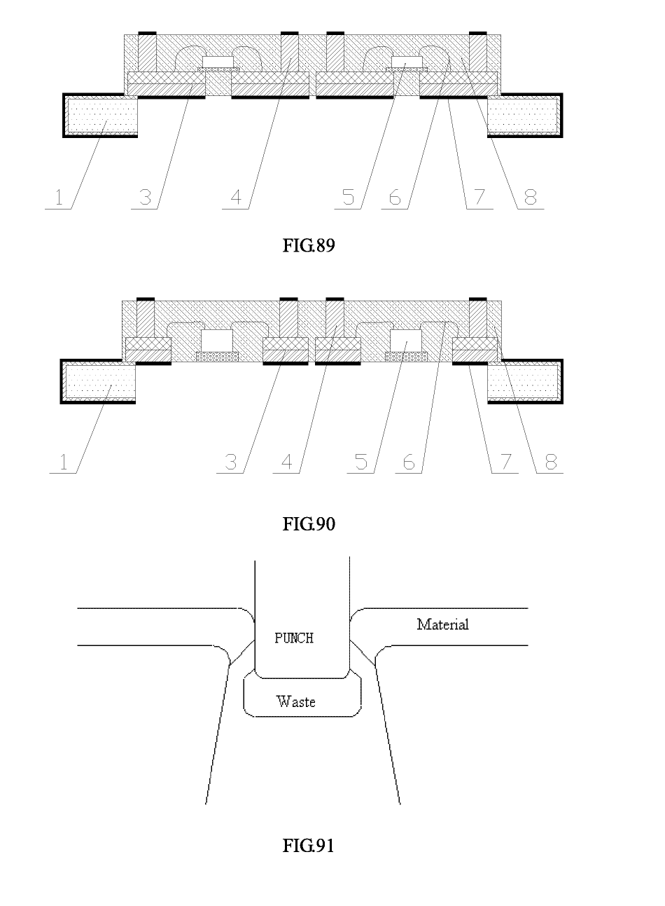

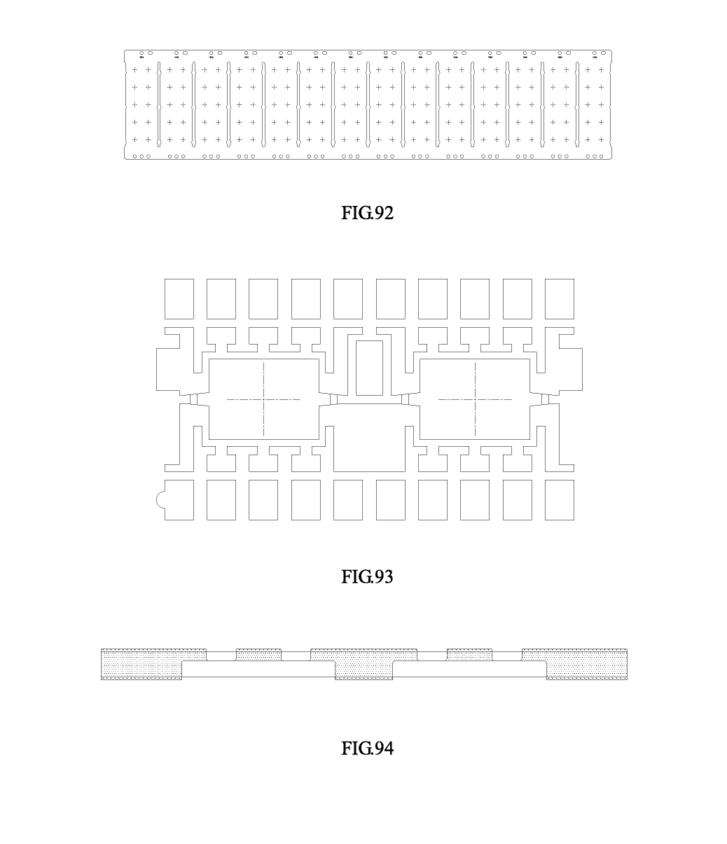

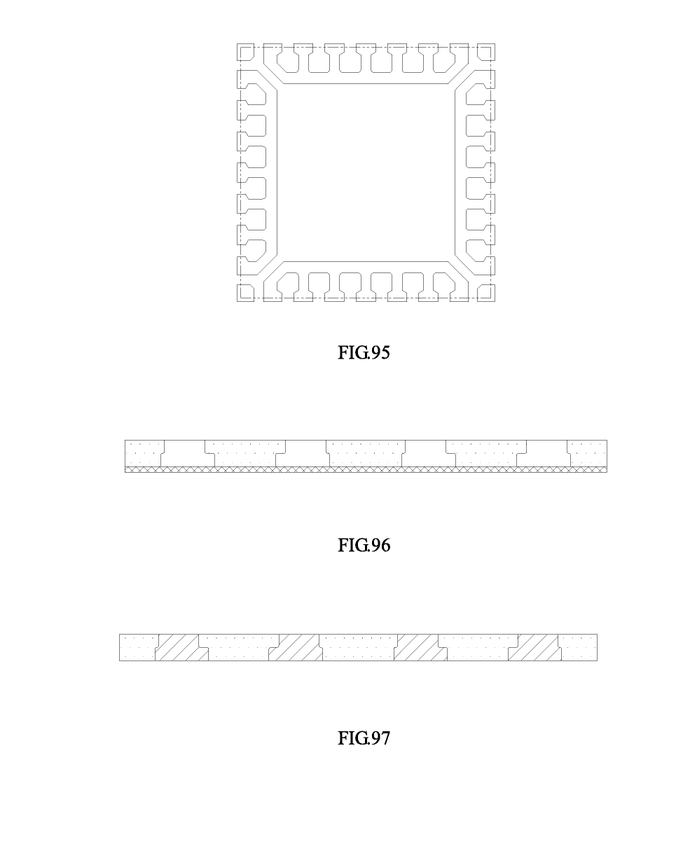

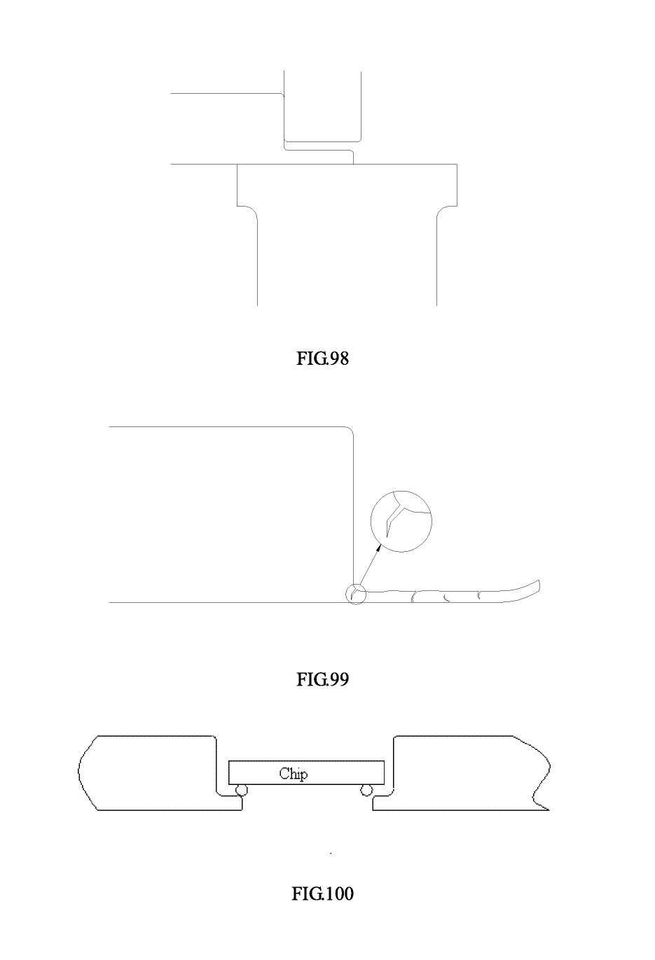

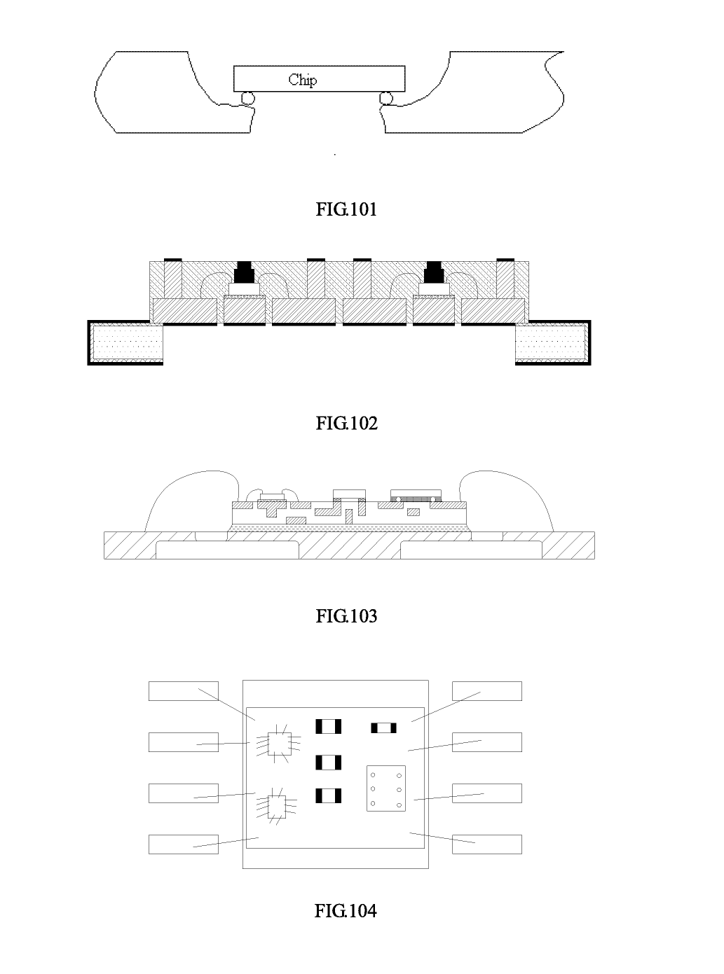

Referring to FIG. 89 and FIG. 90, the eighth embodiment differs from the first embodiment in that the metal circuit board structure does not include a die pad 2; and the chip 5 is normally mounted on the top surface of a metal substrate frame 1 or between the top surfaces of the leads 3.

What is claimed is:

1. A processing method for manufacturing a first-packaged and later-etched normal chip three dimension system-in-package metal circuit board structure, comprising:
step 1: providing a metal substrate;
step 2: pre-plating a surface of the metal substrate with a copper material,
wherein the surface of the metal substrate is pre-plated with a layer of copper material;
step3: applying a photoresist film,
wherein a top surface and a bottom surface of the metal substrate which have been pre-plated with the copper material in step 2 are respectively pasted with the photoresist film which can be exposed and developed;
step 4: removing a part of the photoresist film on the top surface of the metal substrate,
wherein the top surface of the metal substrate, which has been pasted with the photoresist film in step 3 is exposed and developed which a pattern using an exposure and development equipment, and the part of the photoresist film in the pattern is removed, so as to expose a region of the top surface of the metal substrate to be plated with a metal wiring layer later;
step 5: plating with the metal wiring layer,
wherein the region of the top surface of the metal substrate from which the part of the photoresist film has been removed in step 4 is plated with the metal wiring layer, so that a die pad and a lead are formed on the top surface of the metal substrate;
step 6: applying a photoresist film,
wherein the top surface of the metal substrate which has been plated with the metal wiring layer in step 5 is pasted with the photoresist film which can be exposed and developed;
step 7: removing a part of the photoresist film on the top surface of the metal substrate,
wherein the top surface of the metal substrate which has been pasted with the photoresist film in step 6 is exposed and developed with a pattern using an exposure and development equipment, and the part of the photoresist film in a pattern is removed, so as to expose a region of the top surface of the metal substrate to be plated with a conductive pillar later;
step 8: plating with the conductive pillar,
wherein the region of the top surface of the metal substrate from which a part of the photoresist film has been removed in step 7 is plated with the conductive pillar;
step 9: removing the photoresist film,
wherein the photoresist film on the surface of the metal substrate is removed;
step 10: bonding die,
wherein a chip is embedded in a top surface of the die pad formed in step 5 by coating with a conductive or non-conductive adhesive material;
step 11: bonding a metal wire,
wherein the metal wire is bonded between a top surface of the chip and the lead formed in step 5;
step 12: molding with an epoxy resin,
wherein the molding with the epoxy resin for protecting is performed on the top surface of the metal substrate after the bonding die and the metal wire bonding have been performed;
step 13: grinding a surface of the epoxy resin,
wherein the surface of the epoxy resin is ground after the molding with the epoxy resin has been performed in step 12;
step 14: applying a photoresist film,
wherein the top surface and the bottom surface of the metal substrate are pasted with the photoresist film which can be exposed and developed after the surface of the epoxy resin has been ground in step 13;
step 15: removing a part of the photoresist film on the bottom surface of the metal substrate,
wherein the bottom surface of the metal substrate, which has been pasted with the photoresist film in step 14, is exposed and developed with a pattern using an exposure and development equipment, and the part of the photoresist film in the pattern is removed, so as to expose a region of the bottom surface of the metal substrate to be etched later;
step 16: etching,
wherein chemical etching is performed in the region of the bottom surface of the metal substrate from which the part of the photoresist film has been removed in step 15;
step 17: removing the photoresist film,
wherein the photoresist film on the surface of the metal substrate is removed, the photoresist film is removed by softening with chemicals and cleaning with high pressure water; and
step 18: plating with an anti-oxidizing metal layer or coating with an organic solderability preservative,
wherein an exposed surface of the metal substrate surface from which the photoresist film has been removed in step 17 is plated with the anti-oxidizing metal layer or is coated with the organic solderability preservative.

2. A processing method for manufacturing a first-packaged and later-etched normal chip three dimension system-in-package metal circuit board structure, comprising:
step 1: providing a metal substrate;
step 2: plating a surface of the metal substrate with a copper material,
wherein the surface of the metal substrate is plated with a layer of copper material;
step3: applying a photoresist film,
wherein a top surface and a bottom surface of the metal substrate which have been pre-plated with the copper material in step 2 are respectively pasted with the photoresist film which can be exposed and developed;
step 4: removing a part of the photoresist film on the top surface of the metal substrate,
wherein the top surface of the metal substrate which has been pasted with the photoresist film in step 3 is exposed and developed with a pattern using an exposure and development equipment, and the part of the photoresist film in the pattern is removed, so as to expose a region of the top surface of the metal substrate to be plated with a metal wiring layer later;
step 5: plating with the metal wiring layer,
wherein the region of the top surface of the metal substrate from which a part of the photoresist film has been removed in step 4 is plated with the metal wiring layer, so that a die pad and a lead are formed on the top surface of the metal substrate;
step 6: applying a photoresist film,
wherein the top surface of the metal substrate which has been plated with the metal wiring layer in step 5 is pasted with the photoresist film which can be exposed and developed;
step 7: removing a part of the photoresist film on the top surface of the metal substrate,
wherein the top surface of the metal substrate which has been pasted with the photoresist film in step 6 is exposed and developed with a pattern using an exposure and development equipment, and the part of the photoresist film in the pattern is removed, so as to expose a region of the top surface of the metal substrate to be plated with a conductive pillar later;
step 8: plating with the conductive pillar,
wherein the region of the top surface of the metal substrate from which a part of the photoresist film has been removed in step 7 is plated with the conductive pillar;
step 9: removing the photoresist film,
wherein the photoresist film on the surface of the metal substrate is removed;
step 10: bonding die,
wherein a chip is embedded in a top surface of the die pad formed in step 5 by coating with a conductive or non-conductive adhesive material;
step 11: bonding a metal wire,
wherein the metal wire is bonded between a top surface of the chip and the lead formed in step 5;
step 12: molding with an epoxy resin,
wherein the molding with the epoxy resin for protecting is performed on the top surface of the metal substrate after the bonding die and the metal wire bonding have been performed;
step 13: grinding a surface of the epoxy resin,
wherein the surface of the epoxy resin surface is ground after molding with the epoxy resin has been performed in step 12;
step 14: applying a photoresist film,
wherein the top surface and the bottom surface of the metal substrate are pasted with the photoresist film which can be exposed and developed after the surface of the epoxy resin has been ground in step 13;
step 15: removing a part of the photoresist film on the bottom surface of the metal substrate,
wherein the bottom surface of the metal substrate, which has been pasted with the photoresist film in step 14, is exposed and developed with a pattern using an exposure and development equipment, and the part of the photoresist film in the pattern is removed, so as to expose a region of the bottom surface of the metal substrate to be etched later;
step 16: etching,
wherein chemical etching is performed in the region of the bottom surface of the metal substrate from which the part of the photoresist film has been removed in step 15;
step 17: removing the photoresist film,
wherein the photoresist film on the surface of the metal substrate is removed;
step 18: coating the bottom surface of the metal substrate with solder mask or photosensitive non-conductive adhesive material,
wherein the bottom surface of the metal substrate is coated with the solder mask or the photosensitive non-conductive adhesive material after the photoresist film has been removed in step 17;
step 19: exposing and developing to form a window,
wherein the solder mask or photosensitive non-conductive adhesive material with which the bottom surface of the metal substrate is coated is exposed and developed using an exposure and development equipment to form the window, so as to expose a region of the bottom surface of the metal substrate to be plated with a high conductivity metal layer later;
step 20: plating with the high conductivity metal layer,
wherein a region of the window formed in the solder mask or the photosensitive non-conductive adhesive material on the bottom surface of the metal substrate in step 19 is plated with the high conductivity metal layer; and
step 21: plating with an anti-oxidizing metal layer or coating with an organic solderability preservative,
wherein an exposed surface of the metal substrate is plated with the anti-oxidizing metal layer or be coated with the organic solderability preservative.

3-4. (canceled)

5. A first-packaged and later-etched normal chip three dimension system-in-package metal circuit board structure, comprising: a metal substrate frame (1); a die pad (2) and a lead (3) provided in the metal substrate frame (1); a conductive pillar (4) provided on a top surface of the lead (3); a chip (5) is mounted normally on a top surface of the die pad (2) by a conductive or non-conductive adhesive material; a metal wire (6) via which a top surface of the chip (5) is connected to a top surface of the lead (3); a molding material or epoxy resin (8) with which a periphery region of the die pad (2), the lead (3), the conductive pillar (4), the chip (5) and the metal wire (6) is encapsulated, with the molding material or epoxy resin (8) being flushed with a top of the conductive pillar (4); and an anti-oxidizing layer or an organic solderability preservative (7) provided on a surface of the metal substrate frame (1), the die pad (2), the lead (3) and the conductive pillar (4) exposed from the molding material or epoxy resin (8).

6. The first-packaged and later-etched normal chip three dimension system-in-package metal circuit board structure of claim 5, wherein multi-turn conductive pillars (4) are provided.

7. The first-packaged and later-etched normal chip three dimension system-in-package metal circuit board structure of claim 5, wherein a passive device (11) is connected across the top surface of the leads (3).

8. The first-packaged and later-etched normal chip three dimension system-in-package metal circuit board structure of claim 5, wherein an electrostatic discharge coil (12) is provided between the die pad (2) and the lead (3), and the top surface of the chip (5) is connected to a top surface of the electrostatic discharge coil (12) via the metal wire (6).

9. The first-packaged and later-etched normal chip three dimension system-in-package metal circuit board structure of claim 7, wherein an electrostatic discharge coil (12) is provided between the die pad (2) and the lead (3), and the top surface of the chip (5) is connected to a top surface of the electrostatic discharge coil (12) via the metal wire (6).

10. The first-packaged and later-etched normal chip three dimension system-in-package metal circuit board structure of claim 5, wherein a plurality of die pads (2) are provided, the chip (5) is provided on each of the plurality of die pads (2), and the top surfaces of the chips (5) are connected via the metal wire (6).

11. The first-packaged and later-etched normal chip three dimension system-in-package metal circuit board structure of claim 7, wherein a plurality of die pads (2) are provided, the chip (5) is provided on each of the plurality of die pads (2), and the top surfaces of the chips (5) are connected via the metal wire (6).

12. The first-packaged and later-etched normal chip three dimension system-in-package metal circuit board structure of claim 8, wherein a plurality of die pads (2) are provided, the chip (5) is provided on each of the plurality of die pads (2), and the top surfaces of the chips (5) are connected via the metal wire (6).

13. The first-packaged and later-etched normal chip three dimension system-in-package metal circuit board structure of claim 9, wherein a plurality of die pads (2) are provided, the chip (5) is provided on each of the plurality of die pads (2), and the top surfaces of the chips (5) are connected via the metal wire (6).

14. The first-packaged and later-etched normal chip dimension system-in-package metal circuit board structure of claim 5, wherein a second chip (13) is mounted normally on the top surface of the chip (5), and the second chip (13) is connected to the lead (3) via the metal wire (6).

15. The first-packaged and later-etched normal chip three dimension system-in-package metal circuit board structure of claim 7, wherein a second chip (13) is normally mounted on the top surface of the chip (5), and the second chip (13) is connected to the lead (3) via the metal wire (6).

16. The first-packaged and later-etched normal chip three dimension system-in-package metal circuit board structure of claim 8, wherein a second chip (13) is normally mounted on the top surface of the chip (5), and the second chip (13) is connected to the lead (3) via the metal wire (6).

17. The first-packaged and later-etched normal chip three dimension system-in-package metal circuit board structure of claim 9, wherein a second chip (13) is normally mounted on the top surface of the chip (5), and the second chip (13) is connected to the lead (3) via the metal wire (6).

18. The first-packaged and later-etched normal chip three dimension system-in-package metal circuit board structure of claim 10, wherein a second chip (13) is normally mounted on the top surface of the chip (5), and the second chip (13) is connected to the lead (3) via the metal wire (6).

19. The first-packaged and later-etched normal chip three dimension system-in-package metal circuit board structure of claim 11, wherein a second chip (13) is normally mounted on the top surface of the chip (5), and the second chip (13) is connected to the lead (3) via the metal wire (6).

20. The first-packaged and later-etched normal chip three dimension system-in-package metal circuit board structure of claim 12, wherein a second chip (13) is normally mounted on the top surface of the chip (5), and the second chip (13) is connected to the lead (3) via the metal wire (6).

21. The first-packaged and later-etched normal chip three dimension system-in-package metal circuit board structure of claim 13, wherein a second chip (13) is normally mounted on the top surface of the chip (5), and the second chip (13) is connected to the lead (3) via the metal wire (6).

22. The first-packaged and later-etched normal chip three dimension system-in-package metal circuit board structure of claim 5, wherein a second conductive pillar (14) is provided on the top surface of the lead (3), a second chip (13) is flipped on the second conductive pillar (14), the second chip (13) is located above the chip (5), and the second conductive pillar (14) and the second chip (13) are located inside the molding material (8).

23-41. (canceled)
